(19) United States
(12) Patent Application Publication
(10) Pub. No.: US 2026/0040562 A1
(43) Pub. Date: Feb. 5, 2026

(54) PLUG FOR PROTECTION OF BACKSIDE SOURCE FORMATION OF VERTICAL PLANAR MEMORY CELLS

(71) Applicant: Micron Technology, Inc., Boise, ID (US)

(72) Inventors: Masaaki Higuchi, Yokohama (JP); Yoshiaki Fukuzumi, Yokohama (JP)

(21) Appl. No.: 19/275,748

(22) Filed: Jul. 21, 2025

Related U.S. Application Data
(60) Provisional application No. 63/677,538, filed on Jul. 31, 2024.

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

Methods, systems, and devices for formation of an apparatus including a plug for protection of backside source formation of vertical planar memory cells are described. A plug structure within an apparatus may reduce exposure of other portions of the apparatus to a source material during a backside source formation process. For example, the plug may be formed between memory cell pillars and a substrate. The plug may protect the source material from entering via any spaces between memory cell pillars. Each memory cell pillar may include or be coupled with bit line structure that is in contact with the plug. During backside source formation, the diffused materials may etch the plug, and may not enter other areas of the apparatus. The plug material may be deposited directly in a channel, or a separator material may be deposited first to further protect the apparatus during the backside source formation.

### CROSS REFERENCE

The present Application for Patent claims priority to U.S. Patent Application No. 63/677,538 by Higuchi et al., entitled “PLUG FOR PROTECTION OF BACKSIDE SOURCE FORMATION OF VERTICAL PLANAR MEMORY CELLS,” filed Jul. 31, 2024, which is assigned to the assignee hereof, and which is expressly incorporated by reference in its entirety herein.

### TECHNICAL FIELD

The following relates to one or more systems for memory, including an apparatus including a plug for protection of backside source formation of vertical planar memory cells.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system, including an apparatus, that supports formation of the apparatus including a plug for protection of backside source formation of vertical planar memory cells in accordance with examples as disclosed herein.

FIGS. 2A through 2I show examples of memory architectures that support formation of an apparatus including a plug for protection of backside source formation of vertical planar memory cells in accordance with examples as disclosed herein.

FIGS. 3A through 3O show examples of memory architectures that support formation of an apparatus including a plug for protection of backside source formation of vertical planar memory cells in accordance with examples as disclosed herein.

FIGS. 4A and 4B show examples of memory architectures that support formation of an apparatus including a plug for protection of backside source formation of vertical planar memory cells in accordance with examples as disclosed herein.

FIGS. 5A and 5B show examples of memory architectures that support formation of an apparatus including a plug for protection of backside source formation of vertical planar memory cells in accordance with examples as disclosed herein.

FIGS. 6 and 7 show flowcharts illustrating a method or methods that support formation of an apparatus including a plug for protection of backside source formation of vertical planar memory cells in accordance with examples as disclosed herein.

### DETAILED DESCRIPTION

Some memory systems (e.g., apparatuses) include vertical planar memory cells, in which planar cell transistors (e.g., NAND memory cells) may be connected within a trench-like structure, for example, to form a more scaled memory array than some other arrays in which a cylinder-like structure or some other structure may be used for memory cells. A backside source formation process may be used to form a source for one or more of the memory cells by flipping the apparatus over and depositing source materials from the back side (e.g., by removing the substrate or through the substrate using, for example, oxide-nitride-oxide (ONO) etching and poly diffusion). In some vertical planar cell structures, such as trench-shaped structures, there may be some spaces between memory cell pillars such that, during the backside source formation, a source material may enter other (e.g., unintended) regions in the apparatus, which may reduce efficiency, reduce control of a voltage threshold of the cell, and reduce reliability overall, among other examples.

Techniques, systems, and devices described herein provide for a plug structure within an apparatus (e.g., a memory system) to reduce exposure of other portions of the apparatus to the source material during a backside source formation process. For example, the plug may be formed between memory cell pillars within the trench and a corresponding substrate. The plug may be filled with polysilicon material, for example, to protect the source material from entering via any spaces between memory cell pillars. In some examples, the plug may be a T-shaped plug that extends along and underneath the trench including multiple memory cell pillars. The plug may have a first thickness below the memory array and may be reduced to a second thickness in the channels within each memory cell pillar. Each memory cell pillar may thereby include a channel of polysilicon material that is in contact with the same plug of polysilicon material. During backside source formation, the diffused materials may etch the polysilicon, and may not enter other areas of the apparatus. In some examples, the plug material may be deposited directly in a channel within a stack of materials. Additionally, or alternatively, a separator material may be deposited first, and the plug material may be deposited within a cavity below the separator material, such that the separator material may further protect the remainder of the apparatus during the backside source formation.

In addition to applicability in apparatuses as described herein, techniques for formation of an apparatus including a plug for protection of backside source formation of vertical planar memory cells may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing diffusion of a source material during a backside source formation process, which may reduce unintended effects of the source material entering other areas of an apparatus, thereby reducing latency, improving reliability of the apparatus, improving response times, or otherwise improve user experience, among other benefits.

In addition to applicability in apparatuses as described herein, techniques for formation of an apparatus including a plug for protection of backside source formation of vertical planar memory cells may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing an amount of source material, among other materials, that is diffused into an apparatus, improving reliability of the apparatus, and eliminating or otherwise reducing production processes and complexity, which may result in lowered production emissions, may extend the life of electronic devices and thereby reduce electronic waste, among other benefits.

Features of the disclosure are illustrated and described in the context of systems, apparatuses, devices, and circuits. Features of the disclosure are further illustrated and described in the context of memory architectures and flowcharts.

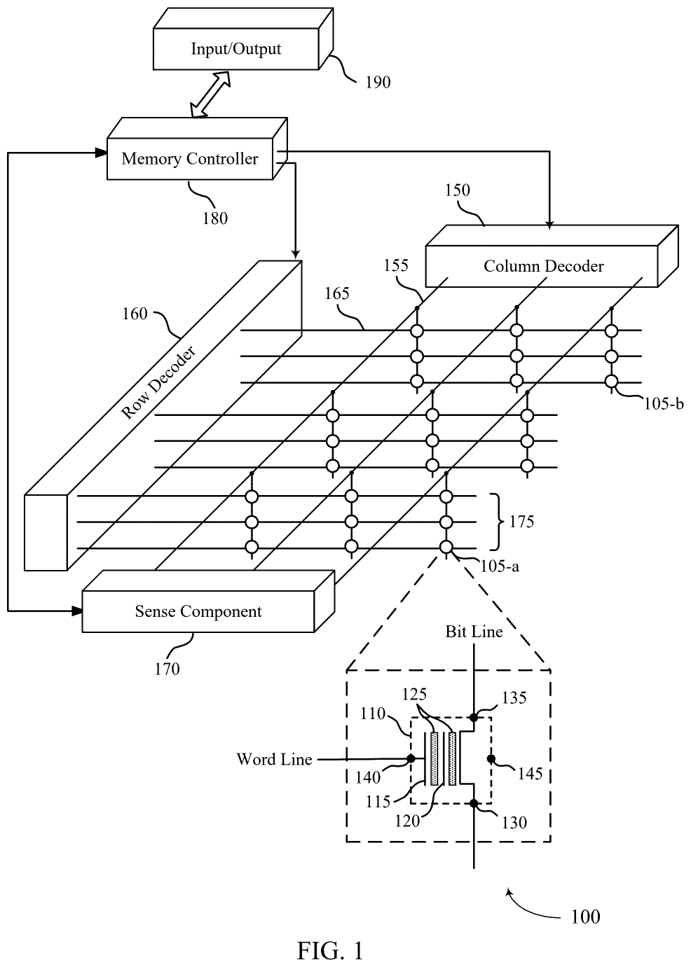

FIG. 1 shows an example of an apparatus 100 (e.g., a memory system, a memory device) that supports formation of an apparatus including a plug for protection of backside source formation of vertical planar memory cells in accordance with examples as disclosed herein. FIG. 1 is an illustrative representation of various components and features of the apparatus 100. As such, the components and features of the apparatus 100 are shown to illustrate functional interrelationships, and not necessarily physical positions within the apparatus 100. Further, although some elements included in FIG. 1 are labeled with a numeric indicator, some other corresponding elements are not labeled, even though they are the same or would be understood to be similar, in an effort to increase visibility and clarity of the depicted features.

The apparatus 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, an apparatus 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, the apparatus 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105.

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of the apparatus 100.

Some apparatuses may include vertical planar memory cells, in which planar cell transistors may be connected within a trench-like structure to form a more scaled memory array than some other arrays in which a cylinder-like structure or some other structure may be used for memory cells. A backside source formation process may be used to form a source for one or more of the memory cells by flipping an apparatus over and depositing source materials from the back side (e.g., by removing the substrate or through the substrate using, for example, ONO etching and poly diffusion). In some vertical planar cell structures, such as trench-shaped structures, there may be some spaces between memory cell pillars such that, during the backside source formation, a source material may enter other (e.g., unintended) regions in the apparatus, which may reduce efficiency, reduce control of a voltage threshold of the cell, and reduce reliability overall, among other examples.

As described herein, the apparatus 100 may be formed with a plug structure to reduce exposure of other portions of the apparatus 100 to the source material during a backside source formation process. For example, the plug may be formed between memory cell pillars within the trench and a corresponding substrate. The plug may be filled with polysilicon material to protect the source material from entering via any spaces between memory cell pillars. In some examples, the plug may be a T-shaped plug that extends along and underneath the trench including multiple memory cell pillars. The plug may have a first thickness below the memory array and may be reduced to a second thickness in the channels within each memory cell pillar. Each memory cell pillar may thereby include a channel of polysilicon material that is in contact with the same plug of polysilicon material. During backside source formation, the diffused materials may etch the polysilicon, and may not enter other areas of the apparatus 100. In some examples, the plug material may be deposited directly in a channel within a stack of materials. Additionally, or alternatively, a separator material may be deposited first, and the plug material may be deposited within a cavity below the separator material, such that the separator material may further protect the remainder of the apparatus 100 during the backside source formation.

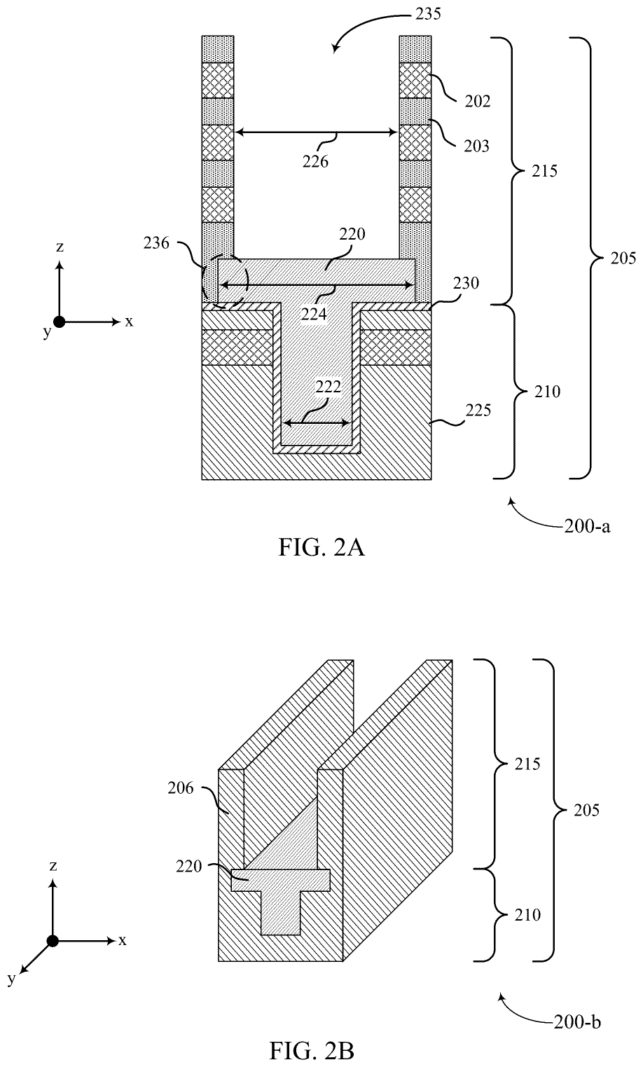

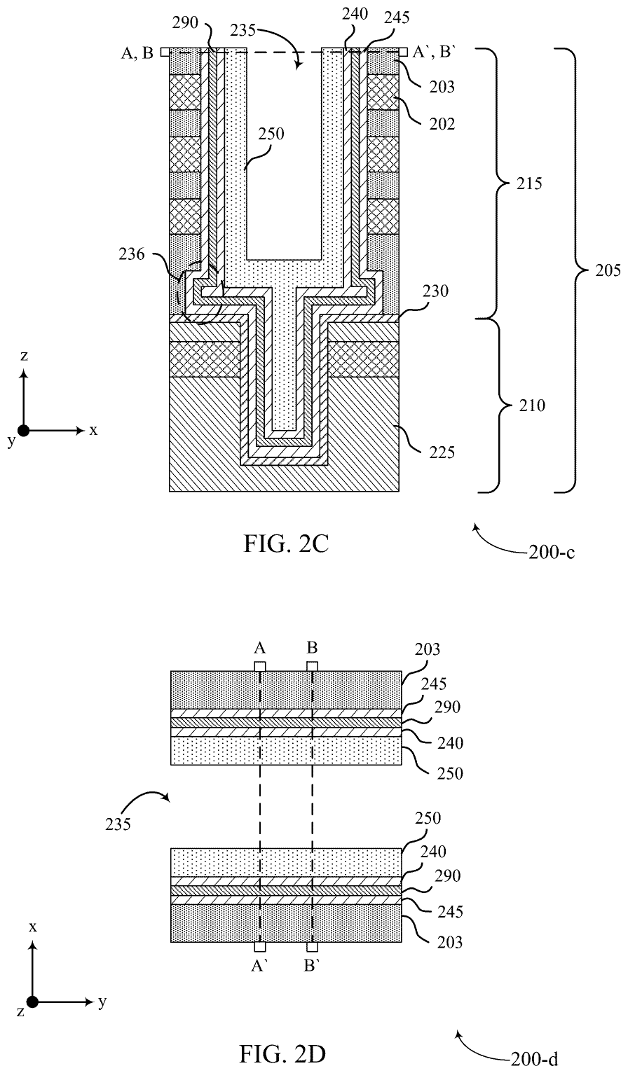

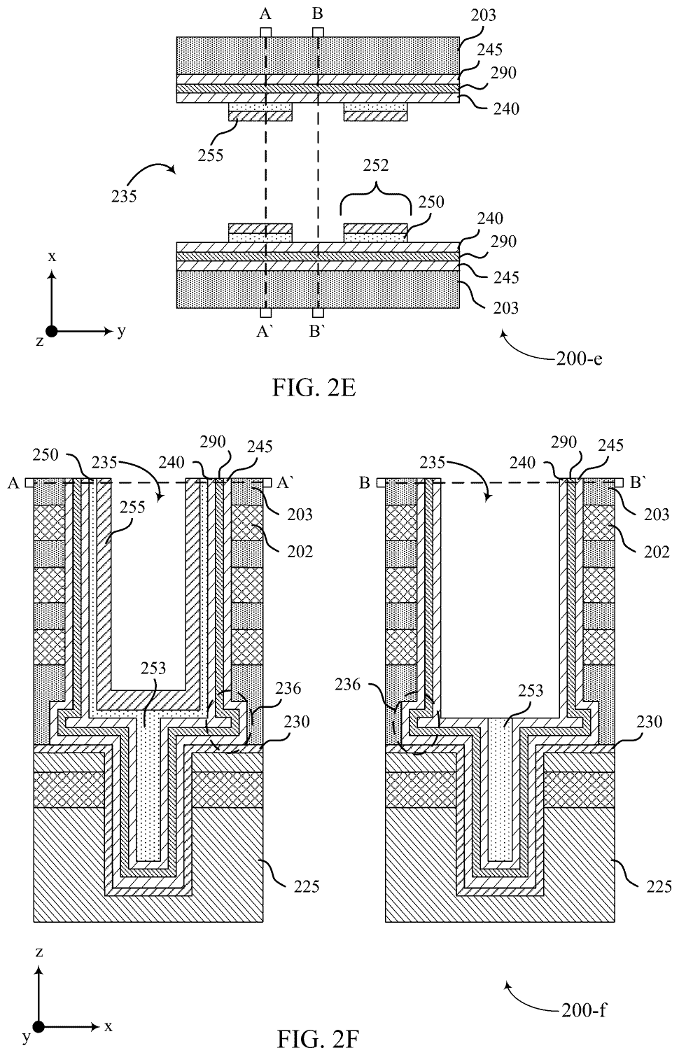

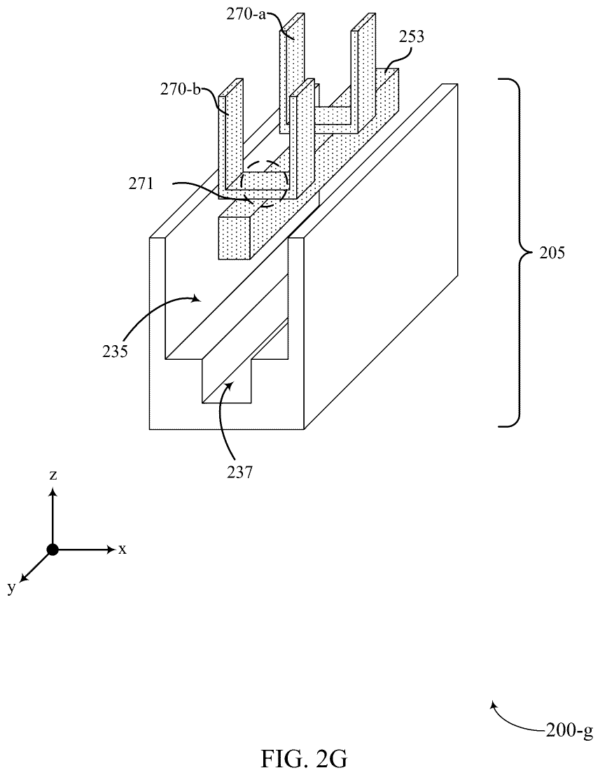

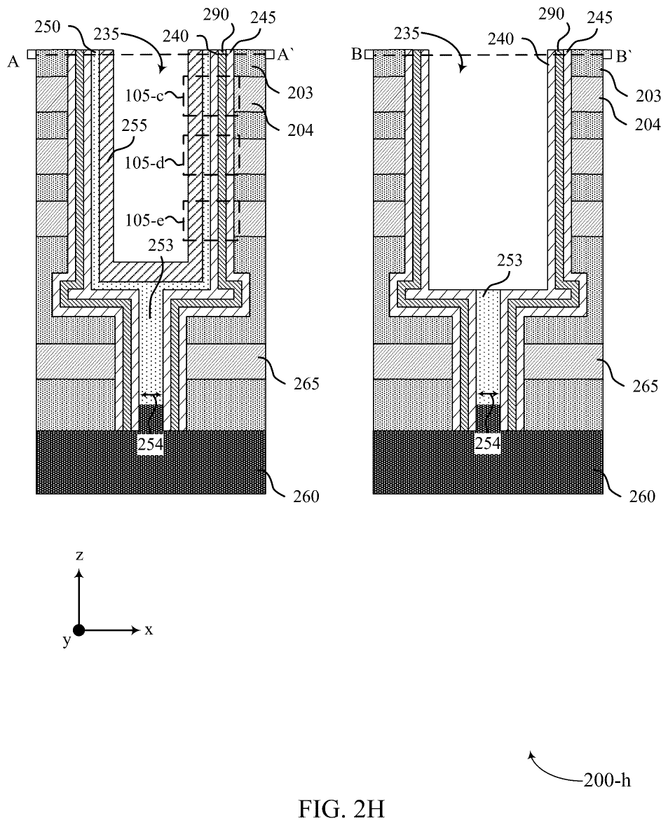

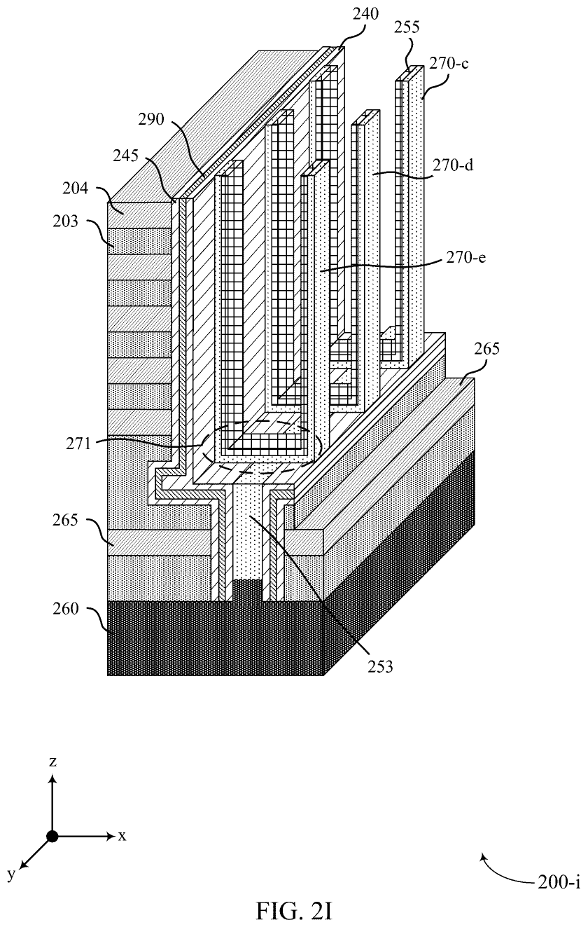

FIGS. 2A through 2I show examples of memory architectures 200 after various processing steps that support formation of a plug for protection of backside source formation of vertical planar memory cells in accordance with examples as disclosed herein. The memory architecture 200 may be an example of a portion of an apparatus, such as an apparatus 100. FIGS. 2A through 2I show various views (e.g., diagonal or trimetric views, planar views, other views) of a memory architecture 200, which may be an example of a memory architecture implemented by an apparatus 100, as described with reference to FIG. 1. The memory architectures 200 may illustrate operations associated with forming an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, memory architectures 200-b, 200-g, and 200-i illustrate the memory architecture from trimetric views, where a substrate of the memory architecture may be associated with an xy-plane, and where the memory architecture extends a distance along the z-direction. Additionally, the memory architectures 200-a, 200-c, 200-d, 200-c, 200-f, and 200-h, may illustrate the memory architecture with a cross-sectional and/or planar view, such that a portion of the memory architecture may be removed from the trimetric view to illustrate a cross-section of the memory architecture in the xz-plane, the xy-plane, or both. Although the memory architectures 200 illustrate examples of relative dimensions and quantities of various features, aspects of the memory architectures 200 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 2A through 2I may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 2A illustrates an example of a memory architecture 200-a after a first processing step associated with forming a stack of materials 205 and a sacrificial plug 220. For example, forming the stack of materials 205 may include depositing alternating (e.g., or at least partially alternating) layers of an oxide material 203 and a sacrificial material 202 above a substrate (e.g., a plane or sheet in the xy-plane on which subsequent memory materials may be formed. The substrate may be associated with complementary metal-oxide semiconductor (CMOS) circuitry. In some such examples, depositing the alternating layers may include depositing a layer of the oxide material 203, then depositing a layer of the sacrificial material 202 above the layer of the oxide material 203. Accordingly, the sacrificial material 202 and the oxide material 203 may be similarly deposited to form alternating layers, where the height of the stack of materials 205 may be based on the quantity and height of each of the alternating layers. In some implementations, the oxide material 203 may be a dielectric material, such as silicon oxide, silicon oxycarbide, silicon oxynitride, or silicon nitride. In some implementations, the sacrificial material 202 may be a variation of nitride.

In some examples, the stack of materials 205 may be formed in two or more formation processes. For example, the first level 210 may be formed first, and the second level 215 may be formed after formation of the first level 210. Forming the first level 210 may include depositing one or more layers of an oxide material 225 and one or more layers of the sacrificial material 302. The oxide material 225 may be the same as or different from the oxide material 303 in the second level 315. In some examples, after the first level 210 is formed, the first level 210 may be etched to form a first cavity (not pictured in FIG. 2A) having a first width 222. The first cavity may pass through the first level 210 of the stack of materials 205 in a first direction (e.g., vertical, the z-direction) and a second direction (e.g., horizontal, the y-direction), having a width 222 in a third direction (e.g., the x-direction). The first cavity may not extend fully through the first level 210, such that a portion of oxide material 225 may remain between the first cavity and a substrate, in some examples. The first cavity may be filled with a sacrificial material 230, which may be an oxide material, such as the oxide material 203, or some other material. The second level 215 may then be formed on top of the first level 210 including the cavity filled with the sacrificial material 230. In some examples, as illustrated in FIG. 2A, the sacrificial material 230 may form a liner between the first level 210 and a first layer of oxide material 203 in the second level 215.

After forming the second level 215 of the stack of materials 205, one or more other cavities may be formed. For example, a second cavity 235 may be formed in the second level 215 of the stack of materials 205. The second cavity 235 may be above the first cavity relative to the substrate. The second cavity 235 may pass through the second level 215 of the stack of materials 205 in the first direction (e.g., the z-direction) and the second direction (e.g., the y-direction). The first cavity and the second cavity 235 may be formed via respective etch processes in which materials are removed from the stack of materials 205 to form the cavities. The first cavity may be formed with a first width 222 and the second cavity 235 may be formed with a second width 226, where the second width 226 is greater than the first width 222.

In some examples, a recess 236 may be formed within the stack of materials 205 between the first cavity and the second cavity 235. For example, a portion of a first layer of oxide material 203 in the second level 215 of the stack of materials 205 may be etched to form a recess 236 (e.g., on each side of the stack) that expands a width of the second cavity 235 from the second width 226 to a third width 224 that is greater than the first width 222 and the second width 226.

After forming the stack of materials 205 and the various cavities, a sacrificial plug 220 may be formed within the first cavity and the recess 236. For example, a sacrificial plug material may be deposited within the first cavity and the recess 236 to form the sacrificial plug 220. In some examples, the formation of the sacrificial plug 220 may form the recess 236 (e.g., the sacrificial plug material may etch back or recede a portion of the oxide material 203). Additionally, or alternatively, the sacrificial plug 220 may be formed within the first cavity before formation of the second level 215, and the second level 215 may be formed on top of the sacrificial plug 220. The sacrificial plug 220 may be a T-shaped plug, or some other shape having the first width 222 in the first level 210 of the stack and the third width 224 in the second level 215 of the stack.

FIG. 2B illustrates an example of a memory architecture 200-b after the first processing step associated with forming the sacrificial plug 220 within the stack of materials 205. For example, the memory architecture 200-b illustrates a trimetric view (e.g., a diagonal view) of the stack of materials 205 illustrated in FIG. 2A. For clarity, some features of the stack of materials 205 are not illustrated in FIG. 2B. For example, the material 206 may be a simplified representation of the alternating layers of materials, including the oxide material 203 and the sacrificial material 202, as described with reference to FIG. 2A.

As illustrated in FIG. 2B, after the sacrificial plug 220 is formed, the stack of materials 205 may represent a trench-shape, where the sacrificial plug 220 may be a T-shape that extends horizontally (e.g., in the y-direction) through the stack of materials 205 and further extends vertically (e.g., in the z-direction) in a portion of the first level 210 and a portion of the second level 215.

FIG. 2C illustrates an example of a memory architecture 200-c after a second processing step associated with forming various layers of materials within the stack of materials 205. For example, the sacrificial plug 220 may be removed (e.g., etched, exhumed) from the stack of materials 205, and one or more layers of materials may be deposited or formed within the first cavity, the recess 236, and the second cavity 235 after the sacrificial plug 220 is removed. The layers of materials may include, for example, a first protective liner 245, a storage material 290, and a second protective liner 240. The materials may be deposited and subsequently etched back to form liners that extend along sidewalls of the stack of materials 205. For example, the first protective liner 245 may extend along sidewalls of the stack of materials 205 within the first cavity, within the recess 236, and within the second cavity 235. The storage material 290 may extend along the first protective liner 245 and between the first protective liner 245 and the second protective liner 240. In some examples, the second protective liner 240 may be deposited and subsequently etched such that a shape of the second protective liner 240 may generally be a U-shape within the second level 215. That is, the second protective liner 240 may include, in some examples, fewer or no curves within the recess 236 than the first protective liner 245 and/or the storage material 290.

After the first protective liner 245, the storage material 290, and the second protective liner 240 are formed, a conductive material 250 may be formed (e.g., deposited) over the second protective liner 240 within a remainder of the first cavity and a portion of the second cavity 235. The conductive material 250 may be associated with one or more bit line structures of the apparatus. A size of the second cavity 235 after these depositions of materials may be reduced as compared with the size of the second cavity 235 in FIG. 2A. The conductive material 250 may thereby fill the first cavity, such that the first level 210 is filled with materials. The conductive material 250 may, in some examples, be formed in the shape of a football field goal post, or a rectangular U-shape connected to a vertical post.

FIG. 2D illustrates an example of a memory architecture 200-d after the second processing step described with reference to FIG. 2C. For example, FIG. 2D illustrates the stack of materials 205 from a birds-eye view (e.g., in the xy-plane). The memory architecture 200-d shown in FIG. 2D illustrates a cross-sectional view of the memory architecture 200-c shown in FIG. 2C, as cut across the A-A′ and B-B′ cross-sectional lines.

As shown in FIG. 2D, after the various materials are formed, a top layer of the apparatus may include two sets of material segments. Each set of material segments including the oxide material 203, the first protective liner 245, the storage material 290, the second protective liner 240, and the conductive material 250. The two sets of materials may be sandwiched together with a space (e.g., the second cavity 235) in between the two sets of materials.

Although not pictured in FIG. 2D, it is to be understood that the second cavity 235 may extend some distance into the page in the z-direction, and there may be more conductive material 250 after the distance, as illustrated in FIG. 2C.

FIG. 2E illustrates an example of a memory architecture 200-e after a third processing step associated with etching back the conductive material 250. The memory architecture 200-e illustrates a birds-eye view of the stack of materials 205 (e.g., in the xy-plane). For example, the memory architecture 200-e illustrates a cross-sectional view of the memory architectures 200-f shown in FIG. 2F, as cut across the A-A′ and B-B′ cross-sectional lines.

The third processing step may include, for example, depositing a channel oxide material 255 within the second cavity 235. The channel oxide material 255 may be formed on top of the conductive material 250 and may be formed with a threshold thickness or may be etched back, such that the channel oxide material 255 has a relatively constant thickness within the second cavity 235. In some examples, the formation of the channel oxide material 255 may reduce a thickness of the conductive material 250 within the second cavity 235, as illustrated in FIG. 2E.

The third processing step may further include etching the conductive material 250 and the channel oxide material 255. The etching may be performed using a mask, which may cover some portions of the stack of materials and expose other portions. The conductive material 250 and the channel oxide material 255 within the exposed portions may be removed (e.g., etched, exhumed, or the like). There may be remaining segments 252 of conductive material 250 within the second cavity 235 (e.g., a trench). The conductive material 250 may be etched such that each segment 252 of conductive material is separated from (e.g., not in direct physical contact with) any other segment 252 of the conductive material within the second level 215 of the stack. The channel oxide material 255 may be etched to a similar or the same shape as the conductive material 250. In some examples, the channel oxide material 255 may be formed on top of the conductive material 250 after the etching. Additionally, or alternatively, the channel oxide material 255 may be formed prior to the etching.

FIG. 2F illustrates an example of a memory architecture 200-f after the third processing step described with reference to FIG. 2E. The memory architecture 200-f represents an example of the memory architecture 200-e illustrated in FIG. 2E, but from a horizontal view (e.g., in the xz-plane). The memory architecture 200-f may represent cross sectional views of the memory architecture 200-e when cut across the A-A′ and B-B′ cross-sectional lines.

When cut across the A-A′ cross-sectional line, the memory architecture 200-f may include each of the first protective liner 245, the storage material 290, and the second protective liner 240 extending along sidewalls of the stack of materials 205. The memory architecture 200-f may further include the conductive material 250 within the first level 210 and the second level 215 (e.g., within the second cavity 235). The channel oxide material 255 may further be included within the A-A′ cross-sectional view as a U-shape on top of the conductive material 250 in the second cavity 235. The conductive material 250 within the first level 210 of the stack may be referred to as a plug 253 herein. For example, the plug 253 may include all of the conductive material 250 that extends continuously in the y direction through the stack of materials 205 (e.g., to form a trench-shape). The conductive material 250 that extends from the plug 253 vertically within the second level 215 may be referred to as the segments 252. Thus, when the memory architecture 200-e illustrated in FIG. 2E is cut across the areas that include the segments 252, the conductive material 250 and the channel oxide material 255 are present within the second cavity 235.

However, when cut across the B-B′ cross-sectional line, the view of the memory architecture 200-f may not include the channel oxide material 255 and may not include the conductive material 250 along the sidewalls of the second cavity 235. For example, because of the etching performed in the third processing step, the conductive material 250 may be formed in U-shaped segments (e.g., rectangular U-shaped segments) within the second cavity 235, where the segments 252 extend from the plug 253 horizontally (e.g., in the x-direction) to a sidewall of the second cavity 235 (e.g., to the second protective liner 240), and then vertically (e.g., in the z-direction) along the sidewall of the second cavity 235 (e.g., along the second protective liner 240). The segments 252 may not, however, extend continuously in the x-direction. Instead, the segments 252 may have a threshold thickness in the x-direction due to the etching. In between the segments 252 may be some other insulating material or an absence of material (e.g., air), at least for part of the manufacturing process. As such, the cross-sectional view of the B-B′ cross-section may not include any conductive material 250 extending from the plug 253, and may instead include the plug 253 that terminates at the second cavity 235.

FIG. 2G illustrates an example of a memory architecture 200-g in accordance with an abstracted trimetric view after the third processing step described herein. The memory architecture 200-g is abstracted to improve clarity and highlight the shape of the plug 253 and corresponding bit line structures 270 (e.g., bit line structures 270-a and 270-b), each of which may include the conductive material 250 described with reference to FIGS. 2A through 2F. The plug 253 and the bit line structures 270 may be removed from the stack of materials 205 for illustration purposes only, and it is to be understood that the plug 253 may be within the first cavity 237 and the bit line structures 270 may be within the second cavity 235, as described and illustrated with reference to FIGS. 2A through 2F.

As illustrated in FIG. 2G, the plug 253 may be a rectangular or cubic shape that extends in the y-direction (e.g., horizontally) within a trench formed by the first cavity 237 in the first level of the stack of materials 205. The plug 253 may have a first thickness in the x-direction and a second thickness in the z-direction, where the first and second thicknesses may be the same or different. The plug 253 may provide a continuous and solid base connection point for each of the bit line structures 270, which may protect against a source material being diffused throughout the memory architecture 200-g. The bit line structures 270 may be in direct physical contact with the plug 253 at a base contact region 271, and may otherwise be separated from one another. For example, the bit line structure 270-a may not be in direct physical contact with the bit line structure 270-b. There may be an absence of material or some insulating material between the two bit line structures 270-a and 270-b in the y-direction. The bit line structures 270 may each extend horizontally in the x-direction from the base contact region 271 to sidewalls of the second cavity 235 and may extend vertically in the z-direction within the stack of materials 205 and along sidewalls of the second cavity 235. The bit line structures 270 may be configured as bit lines that may active or select one or more memory cells within the stack (e.g., memory cell pillars). Additionally, or alternatively, the bit line structures 270 may represent examples of conductive lines (e.g., strings) of memory cells 105 coupled between two selectors. For example, the bit line structures 270 may represent a conductive channel between memory cells 105. A bit line may be coupled with a top portion of the bit line structures 270 via a selector, such as a select gate drain selector, a select gate source selector, or some other type of selector. In some examples, a connection between the bit line structures 270 and the plug 253 may be referred to as a selector (e.g., a source side selector, among other examples) and may include a first portion. Each bit line structure 270 may include a first string including a first selector with a first portion and a second string including a second selector with a second portion, where the first and second selectors are coupled with the plug 253.

FIG. 2H illustrates an example of a memory architecture 200-h after a fourth processing step associated with metallization and backside source formation. The memory architecture 200-h illustrates cross-sectional views along the A-A′ and B-B′ cross-sectional lines as described with reference to FIGS. 2E and 2F.

As part of the fourth processing step, a metallization process may be performed to convert the sacrificial material 202 to the metal material 204. The stack of materials may thereby include layers of the oxide material 203 and layers of the metal material 204. The metallization may not alter the structure of the first protective liner 245, the second protective liner 240, the storage material 290, the plug 253, the conductive material 250, or the channel oxide material 255. The plug 253 may have a thickness 254.

The fourth processing step may further include a backside source formation process, in which the source 260 is formed. In some examples, a substrate may be positioned beneath the memory architecture 200-f illustrated in FIG. 2F. As part of the backside source formation, the apparatus may be flipped or otherwise rotated and the substrate may be removed such that the manufacturing system may access a “backside” of the apparatus, which may correspond to a bottom of the first level 210 of the stack of materials 205.

A source material may be deposited from the backside of the apparatus to form the source 260. The source material may include an n+poly-silicon material, some other material, or any combination thereof. The source material deposition may, in some examples, result in phosphorous diffusion, which may degrade a portion of the plug 253 (e.g., in the vertical or z-direction), but may not degrade or otherwise remove all of the plug 253 due to the plug 253 having sufficient thickness 254. As such, the plug 253 may remain during the backside source formation and the source 260 may be in contact with the plug 253 across the entire or most of the thickness 254 (e.g., over a full surface of the plug 253). The source 260 may thereby be formed without any materials entering the second cavity 235 or other unintended areas of the apparatus. Because the plug 253 extends along the y-direction, even in regions of the apparatus where the bit line structures were removed due to etching, the entire structure is protected from the backside source diffusion, including those areas that do not include bit line structures. For example, as illustrated in the B-B′ cross-sectional view of the memory architecture 200-h, the second cavity 235 may not include any of the source material after the formation of the source 260 because the plug 253 may stop the diffusion of the source material elsewhere in the structure.

The layers of metal material 204 may be word lines configured to access memory cells 105-c, 105-d, and 105-e within the respective layer. For example, a memory cell 105 may be formed at each junction of the storage material 290 with a respective layer of the metal material 204 and a respective bit line structure including the conductive material 250. The memory cells 105-c, 105-d, and 105-e illustrated in FIG. 2H may be included in a memory cell pillar, in some examples. The memory cell pillars may be referred to as strings, in some examples (e.g., multiple memory cells 105 connected in series). Although not illustrated, it is to be understood that three more memory cells 105 may be included in the other side of the A-A′ cross-sectional view of the memory architecture 200-h.

A given memory cell 105 may be accessed by activation of both a corresponding word line and a corresponding bit line structure at the same time. The activation of the word lines (e.g., the metal material 204) may be controlled via one or more word line decoders or other circuitry, which may be positioned under the array (e.g., within a substrate or elsewhere in the memory architecture 200-g). The activation of the bit line structures may be controlled via a transistor or other selection circuitry, which may include the plug 253, the source 260, and the selector 265. For example, a voltage may be applied via the source 260, and the voltage that passes through to the plug 253 and corresponding bit line structures may be controlled by the selector 265 (e.g., a gate at least partially surrounding the plug 253, an electrode). The voltage may be referred to as a threshold voltage, in some examples. The selector 265 may be relatively close to the source 260 (e.g., closer than the other layers of the metal material 204 to the n+diffusion point), which may provide for more accurate and reliable control of the threshold voltage (e.g., a gate-source voltage) and corresponding current through the conductive material 250 than if the selector 265 is positioned a further distance from the source 260. In some examples, the bit line structures 270 may represent examples of string lines, and one or more bit lines may extend in the y-direction above the stack of materials 205. The one or more bit lines may be coupled with the bit line structures 270 via one or more other selectors.

FIG. 2I illustrates an example of a memory architecture 200-i after the fourth processing step described herein. The memory architecture 200-i illustrates the memory architecture 200-h from a trimetric viewpoint. That is, a portion of the architecture in the y-direction is further shown in FIG. 2I to further illustrate the bit line structures 270 (e.g., bit line structures 270-c, 270-d, and 270-e) and the spacing between them in more detail than shown in the previous figures.

The source 260 may be formed across a bottom of the structure and may be in contact with a surface of the plug 253 in the x- and y-directions. The selector 265 may include the metal material 204 and may extend along the x- and y-directions around the plug 253. That is, the first protective liner 245, the second protective liner 240, and the storage material 290 may be positioned on each side of the plug 253 between the plug 253 and the selector 265. The protective liners 245 and 240, as well as the storage material 290, may continue to extend vertically through the stack. Multiple memory cells 105 may be formed at junctions of the storage material 290, the word lines (e.g., the layers of the metal material 204) and the bit line structures 270, as described and illustrated in FIG. 2H.

The bit line structures 270 may represent rectangular or curved U-shaped segments that extend from the plug 253. For example, each bit line structure 270 may be in contact with (e.g., coupled with) the plug 253 at a respective base contact region 271. The bit line structure 270 may extend horizontally on each side of the base contact region 271. The bit line structure 270 may extend vertically from the horizontal segments on each side of the base contact region 271 and along sidewalls of the stack of materials including the oxide material 203 and the metal material 204 (e.g., word lines). In some examples, a channel oxide material 255 may be positioned on top of the bit line structures 270. Each bit line structure 270 may be physically separated from (e.g., independent from, not in contact with) each other bit line structure 270. For example, the bit line structure 270-c may not be in direct contact with the bit line structure 270-d or the bit line structure 270-e outside of the base contact regions 271 at which each of the bit line structures 270 contacts the plug 253. In some examples, a region where a bit line structure 270 extends vertically along the second protective liner 240 and corresponding storage material 290 may be referred to as a memory cell pillar, as there may be multiple memory cells 105 stacked in that area (e.g., at each layer of the metal material 204).

As described with reference to FIG. 2H, the selector 265 may be configured to adjust, based on a voltage applied to the selector 265, a current that flows through the plug 253 and corresponding bit line structures 270 from the source 260. The apparatus may thereby select one or more memory cells 105 by activating, using the source 260 and the selector 265, the bit line structures 270-c, 270-d, and 270-c, and activating one or more of the word lines (e.g., the layers of the metal material 204) that are at the same level as the target memory cell(s) 105.

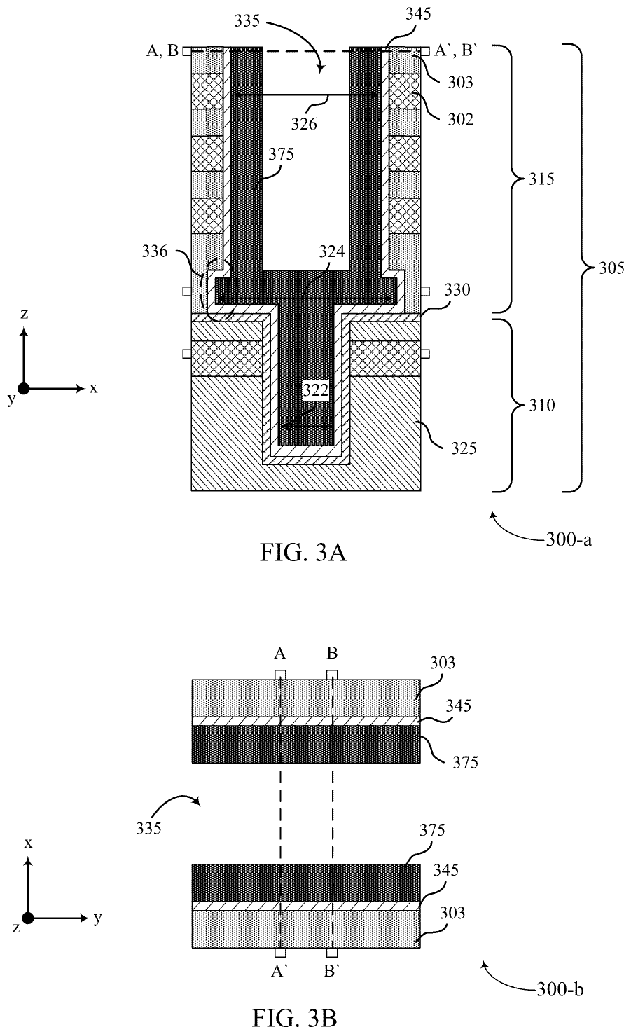

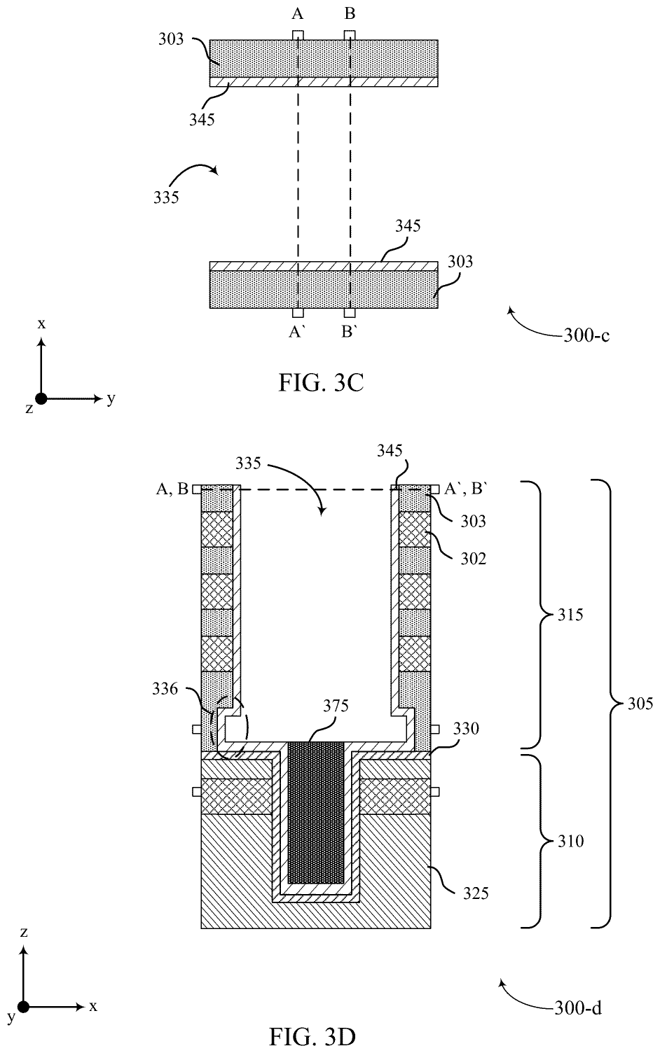

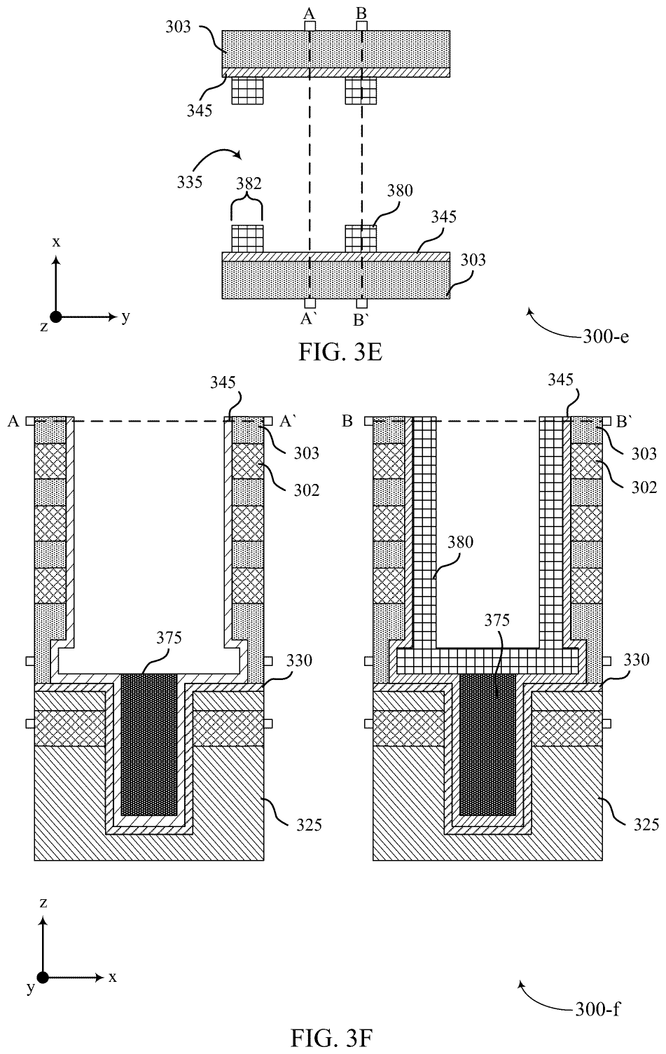

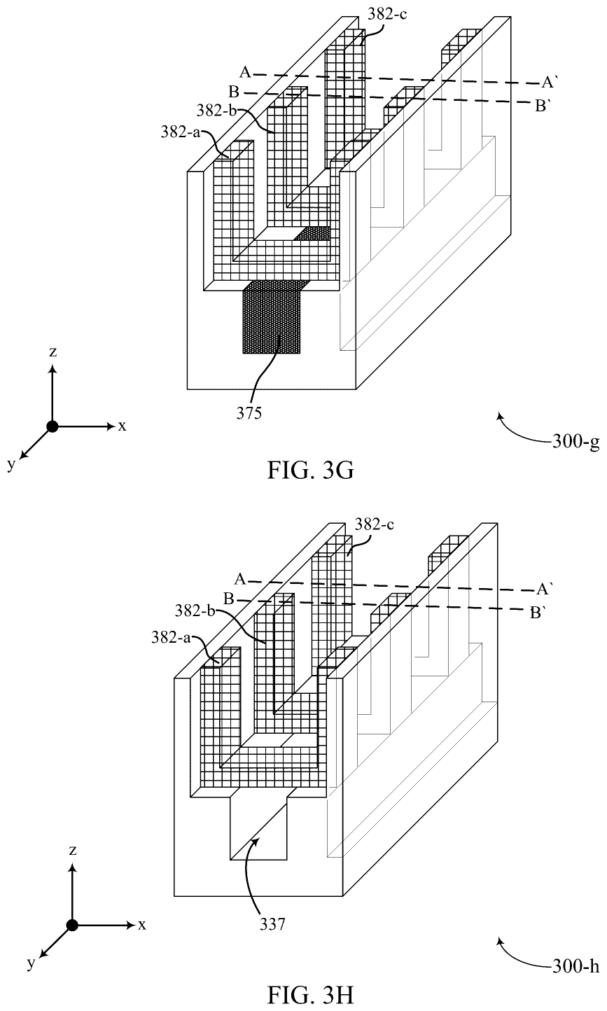

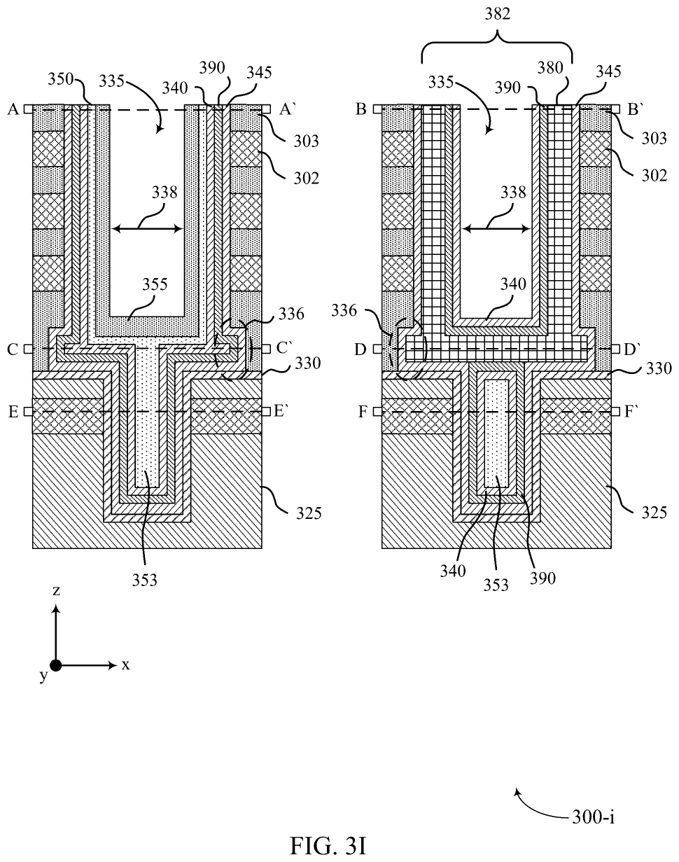

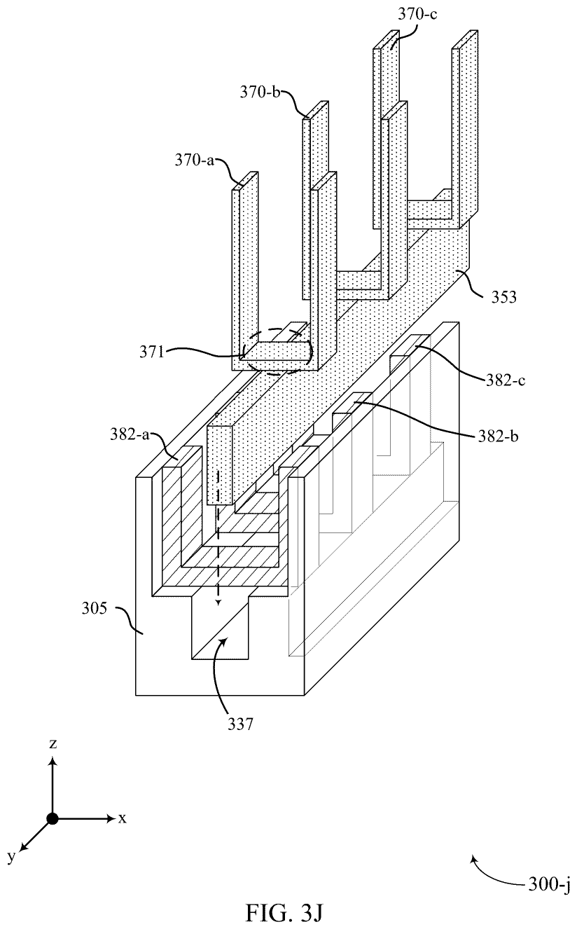

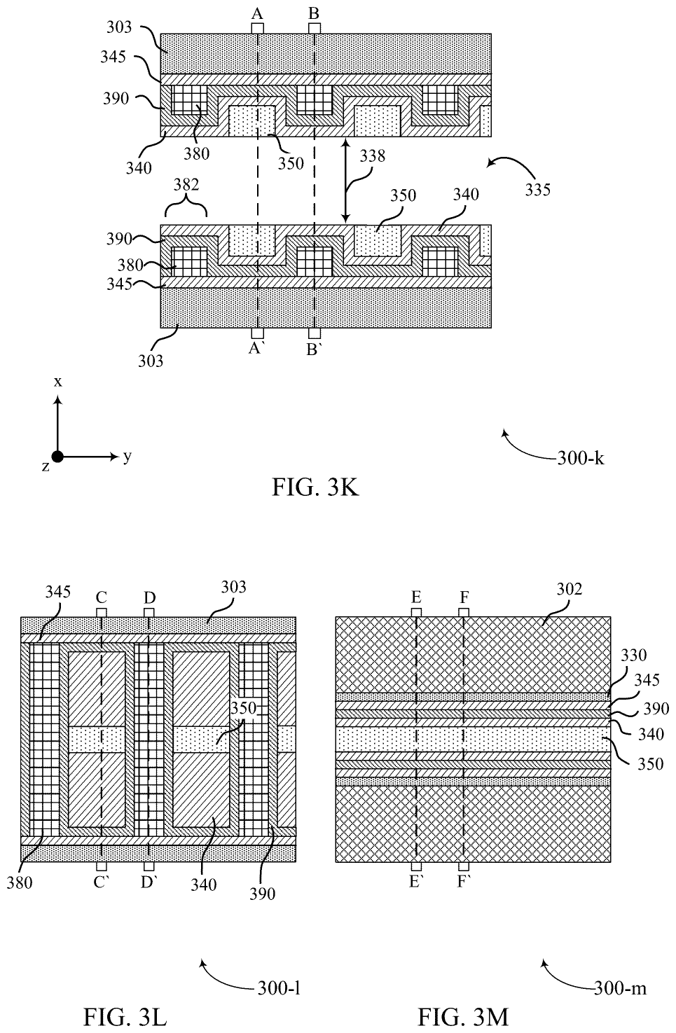

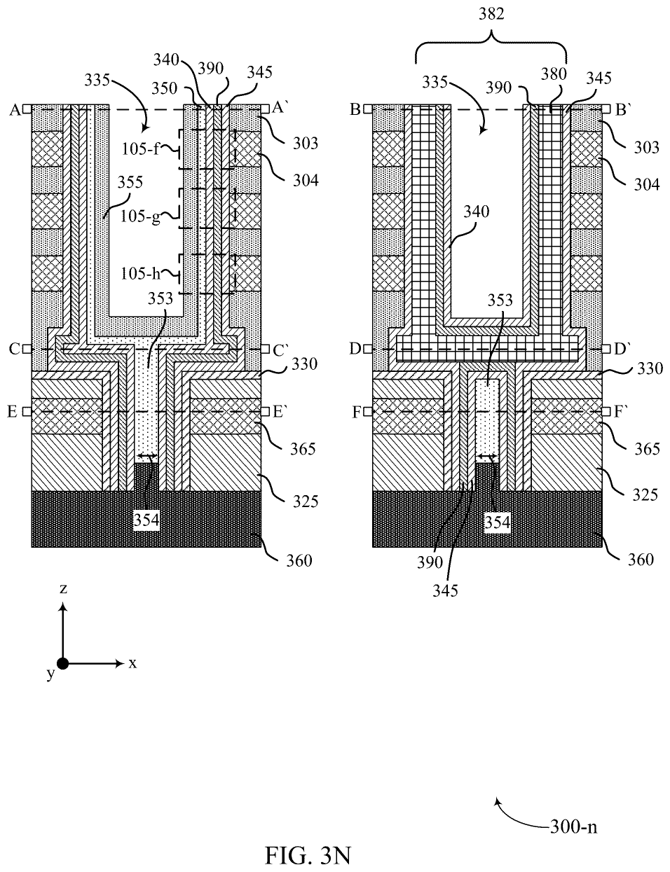

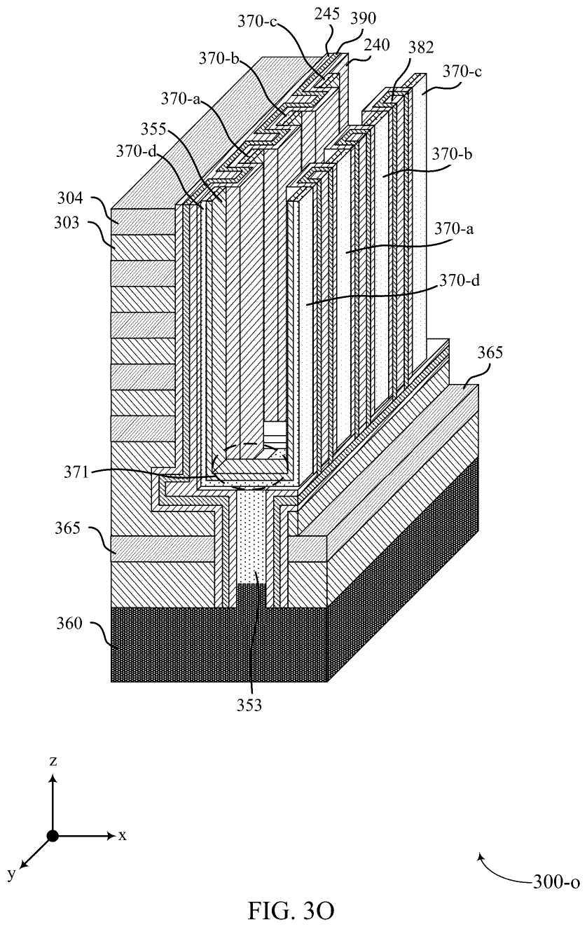

FIGS. 3A through 3O show examples of memory architectures 300 after various processing steps that support formation of a plug for protection of backside source formation of vertical planar memory cells in accordance with examples as disclosed herein. The memory architecture 300 may be an example of a portion of an apparatus, such as an apparatus 100. FIGS. 3A through 3O show various views (e.g., diagonal or trimetric views, planar views, other views) of a memory architecture 300, which may be an example of a memory architecture implemented by an apparatus 100, as described with reference to FIG. 1. The memory architectures 300 may illustrate operations associated with forming an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, memory architectures 300-g, 300-h, 300-j, and 300-o illustrate the memory architecture from trimetric views, where a substrate of the memory architecture may be associated with an xy-plane, and where the memory architecture extends a distance along the z-direction. Additionally, the memory architectures 300-a, 300-b, 300-c, 300-d, 300-e, 300-f, 300-i, 300-k, 300-l, 300-m, and 300-n illustrate the memory architecture with a cross-sectional and/or planar view, such that a portion of the memory architecture may be removed from the trimetric view to illustrate a cross-section of the memory architecture in the xz-plane, the xy-plane, or both. Although the memory architectures 300 illustrate examples of relative dimensions and quantities of various features, aspects of the memory architectures 300 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 3A through 3O may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

In some examples, a first processing step associated with forming a stack of materials 305 and a sacrificial plug may be performed, as described in further detail with reference to FIG. 2A. For example, alternating (e.g., or at least partially alternating) layers of an oxide material 303 or an oxide material 325 and a sacrificial material 302 may be deposited above a substrate (e.g., a plane or sheet in the xy-plane on which subsequent memory materials may be formed. In some examples, the stack of materials 305 may be formed in two or more formation processes. For example, a first level 310 may be formed first, and a second level 315 may be formed after formation of the first level 310. A stack of materials 305 including a first cavity having a first width 322, a second cavity 335 having a second width 326 and a recess having a third width 324 and a sacrificial plug as described with reference to FIG. 2A may thereby be formed.

FIG. 3A illustrates an example of a memory architecture 300-a after a second processing step associated with removal of the sacrificial plug and formation of a sacrificial material 375. For example, the sacrificial plug may be removed after the stack of materials 305 is formed. A protective liner 345 may subsequently be deposited in the first cavity, the recess 336, and the second cavity 335. The protective liner 345 may be deposited and/or etched back to form a liner that extends along sidewalls of the stack of materials 305. After the protective liner 345 is formed, a sacrificial material 375 may be formed. The sacrificial material 375 may be deposited on top of the protective liner 345 and may have a thickness that is greater than a thickness of the protective liner 345, in some examples. The sacrificial material 375 may extend into the recess 336 on each side, and may fill the first cavity in the first level 310 of the stack of materials 305.

FIG. 3B illustrates an example of a memory architecture 300-b after the second processing step described with reference to FIG. 3A. For example, FIG. 3B illustrates the stack of materials 305 from a birds-eye view (e.g., in the xy-plane). The memory architecture 300-b shown in FIG. 3B illustrates a cross-sectional view of the memory architecture 300-a shown in FIG. 3A, as cut across the A-A′ and B-B′ cross-sectional lines.

As shown in FIG. 3B, after the protective liner 345 and the sacrificial material 375 are formed, a top layer of the apparatus may include two sets of material segments, each set including the oxide material 303, the protective liner 345, and the sacrificial material 375. The materials may extend in the x-direction and may have varying thicknesses in the y-direction. The two sets of materials may be sandwiched together with a space (e.g., the second cavity 335) in between the two sets of materials.

Although not pictured in FIG. 3B, it is to be understood that the second cavity 335 may extend some distance into the page in the z-direction, and there may be more sacrificial material 375 after the distance, as illustrated in FIG. 3A.

FIG. 3C illustrates an example of a memory architecture 300-c after a third processing step associated with etching at least a portion of the sacrificial material 375 (e.g., a sacrificial film recess operation). For example, FIG. 3C illustrates the stack of materials 305 from a birds-eye view (e.g., in the xy-plane). The memory architecture 300-c shown in FIG. 3C illustrates a cross-sectional view of the memory architecture 300-d shown and described with reference to FIG. 3D, as cut across the A-A′ and B-B′ cross-sectional lines.

The third processing step may include, for example, a recess of the sacrificial material 375. For example, the sacrificial material 375 may be removed from the second level 315 of the stack of materials 305. In other words, the sacrificial material 375 may be removed from sidewalls of the second cavity 335 and the recess 336. The sacrificial material 375 may remain in the first cavity, in some examples.

As shown in FIG. 3C, after the sacrificial material 375 is recessed, a top layer of the apparatus may include two sets of material segments, each set including the oxide material 303 and the protective liner 345. The materials may extend in the x-direction and may have varying thicknesses in the y-direction. The two sets of materials may be sandwiched together with a space (e.g., the second cavity 335) in between the two sets of materials.

FIG. 3D illustrates an example of a memory architecture 300-d after the third processing step as described with reference to FIG. 3C. The memory architecture 300-d represents an example of the memory architecture 300-c illustrated in FIG. 3C, but from a horizontal view (e.g., in the xz-plane). The memory architecture 300-d may represent cross sectional views of the memory architecture 300-c when cut across the A-A′ and B-B′ cross-sectional lines.

The materials and structure within the memory architecture 300-d may be the same when cut across the A-A′ cross-sectional line as when cut across the B-B′ cross-sectional line. That is, the structure may extend continuously for some distance in the y-direction.

The memory architecture 300-d may include the protective liner 345 extending from the first level 310 through the second level 315 of the stack of materials 305. As described herein, the third processing step may include recessing the sacrificial material 375. Accordingly, the memory architecture 300-d may include the sacrificial material 375 in the first level 310 and not in the second level. The sacrificial material 375 may thereby form a rectangular prism that extends in the y-direction and has a first thickness in the x-direction that is the same as or different from a second thickness of the sacrificial material 375 in the z-direction. The second cavity 335 and the recesses 336 may be empty except for the protective liner 345.

FIG. 3E illustrates an example of a memory architecture 300-e after a fourth processing step associated with forming a separation material 380. For example, FIG. 3E illustrates the stack of materials 305 from a birds-eye view (e.g., in the xy-plane). The memory architecture 300-e shown in FIG. 3E illustrates a cross-sectional view of the memory architecture 300-f shown and described with reference to FIG. 3F, as cut across the A-A′ and B-B′ cross-sectional lines.

The fourth processing step may include depositing and etching a separation material 380. For example, the separation material 380 may be deposited within the second cavity 335. The separation material 380 may be deposited throughout the second cavity 335 and subsequently etched (e.g., using a mask or other etching process) to remove portions of the sacrificial material 380. The remaining separation material 380 may be formed on sidewalls of the protective liner 345 within the second cavity 335. The separation material 380 may be formed as one or more regions 382 (e.g., segments) of separation material 380, as illustrated in FIG. 3E. The separation material 380 may be a silicon oxide material, or some other type of insulating or non-conductive material configured to separate adjacent bit line structures.

FIG. 3F illustrates an example of a memory architecture 300-f after the fourth processing step described with reference to FIG. 3E. The memory architecture 300-f represents an example of the memory architecture 300-e illustrated in FIG. 3E, but from a horizontal view (e.g., in the xz-plane). The memory architecture 300-f may represent cross sectional views of the memory architecture 300-c when cut across the A-A′ and B-B′ cross-sectional lines.

The materials and structure within the memory architecture 300-f may be different when cut across the A-A′ cross-sectional line from when cut across the B-B′ cross-sectional line. The etching of the separation material 380 may form regions 382 of the separation material 380 which may be discrete in the y-direction, such that each separation region 382 may not be in direct physical contact with any other separation region 382. A separation region 382 may correspond to an area of the apparatus that includes a segment of the separation material 380. The segment may be within the U-shape. FIG. 3F illustrates a cross-sectional view of a single separation region 382, but it is to be understood that there may be multiple separation regions 382 dispersed in and out of the page in the y-direction.

The memory architecture 300-f may include the protective liner 345 extending from the first level 310 through the second level 315 of the stack of materials 305. When cut across the A-A′ cross-sectional line, the memory architecture 300-f may be the same as the memory architecture 300-d described with reference to FIG. 3D.

When cut across the B-B′ cross-sectional line, however, the memory architecture 300-d may further include the region 382 of the separation material 380. For example, the separation material 380 may extend in a U-shape (e.g., rectangular U-shaped segments) within the second level 315 of the stack of materials 305. The separation material may be on top of and in direct contact with a top surface of the sacrificial material 375, and may extend along the protective liner 345 on both sides of the sacrificial material 375.

FIG. 3G illustrates an example of a memory architecture 300-g after the fourth processing step described with reference to FIGS. 3E and 3F. The memory architecture 300-g may represent an abstracted trimetric view of the memory architectures 300-e and 300-f. For example, additional portions of the y-direction may be illustrated for clarity. Additionally, the various materials in the stack may not be illustrated for clarity.

The memory architecture 300-g may illustrate how the sacrificial material 375 extends as a rectangular prism in the y-direction with thicknesses in the x- and z-directions. The regions 382 of the separation material 380 may each represent rectangular U-shapes (e.g., three rectangular prism structures formed in a U-shape) that are dispersed above the sacrificial material 375 in the y-direction. For example, the region 382-a may not be in direct physical contact with the region 382-b or the region 382-c. Each region 382 may, based on the etching of the separation material 380, be separated or otherwise isolated in the y-direction.

FIG. 3H illustrates an example of a memory architecture 300-h after a fifth processing step associated with removing the sacrificial material 375. The memory architecture 300-h may represent an abstracted trimetric view of the memory architectures 300-c, 300-f, and 300-g after the sacrificial material 375 is removed. For example, various materials in the stack may not be illustrated for clarity.

The fifth processing step may include removing (e.g., etching, exhuming) the sacrificial material 375 after the separation material 380 is deposited and the region 382 are formed. The removal of the sacrificial material 375 may expose the first cavity 337, which may extend in the y-direction under the region 382-a, 382-b, and 382-c.

FIG. 3I illustrates an example of a memory architecture 300-i after a sixth processing step associated with depositing a conductive material 350. The memory architecture 300-i illustrates a horizontal view of the memory architectures 300-g and 300-h after the sixth processing step and as cut along the A-A′ and B-B′ cross-sectional lines.

The sixth processing step may include deposition of one or more materials, including the storage material 390, a second protective liner 340, the conductive material 350, and the channel oxide material 355. The storage material 390 may be deposited within the second cavity 335 and the first cavity 337 after the separation material 380 is deposited and etched as described with reference to FIG. 3H. The storage material 390 may thereby cover the separation material 380 in the separation region 382 (e.g., as shown in the B-B′ cross-sectional view) as well as the protective liner 345 in between the separation regions 382. In some examples, the storage material 390 may be formed as a liner around sidewalls of the first cavity 337. For example, within the separation regions 382, the storage material 390 may be formed along bottom and sidewalls of the first cavity 337 and along a bottom surface of the storage material 390. The shape of the storage material 390 is described in further detail elsewhere herein, including with reference to FIGS. 3K through 3M.

After formation of the storage material 390, a second protective liner 340 may be deposited. The second protective liner 340 may be deposited on top of the storage material 390 and may have a similar structure. For example, both the storage material 390 and the second protective liner 340 may extend along external sidewalls of each separation region 382 and of the protective liner 345 between each separation region 382. The second protective liner 340 may similarly form a rectangular liner shape within the first cavity 337 underneath each segment of the separation material 380.

After the second protective liner 340 is formed, the conductive material 350 may be deposited. In some examples, the conductive material 350 may be deposited to fill or at least partially fill the second cavity 335 and the first cavity 337 at both the A-A′ and the B-B′ cross-sectional lines. The conductive material 350 may subsequently be etched within the second cavity 335 to be planar, in the x-direction, with the second protective liner 340 in the separation regions 382. For example, the conductive material 350 and the second protective liner 340 may, after formation, be planar such that a width of the second cavity 335 in the x-direction may be continuous over the y-direction, as illustrated and described in further detail elsewhere herein, including with reference to FIGS. 3K through 3M. The conductive material 350 may further fill a remaining portion of the first cavity 337 (e.g., between or within the storage material 390 and the second protective liner 340 beneath the separation material 380.

The conductive material 350 may thereby form a plug 353 that extends continuously in the y-direction beneath the dispersed segments of the separation material 380 in the separation regions 382. The conductive material 350 may further extend into one or more bit lines that extend vertically between the separation regions 382, as illustrated and described in further detail elsewhere herein, including with reference to FIG. 3J.

FIG. 3J illustrates an example of a memory architecture 300-j in accordance with an abstracted trimetric view after the sixth processing step described with reference to FIG. 3I. The memory architecture 300-j is abstracted to improve clarity and highlight the shape of the plug 253 and corresponding bit line structures 370 (e.g., bit line structures 370-a, 370-b, and 370-c), each of which may include the conductive material 350 described with reference to FIGS. 3A through 3I. The plug 353 and the bit line structures 370 may be illustrated as slightly removed from the stack of materials 305 for illustration purposes only, and it is to be understood that the plug 353 may be within the first cavity 337 under the separation regions 382-a, 382-b, and 382-c (e.g., as illustrated by the dashed arrow) and the bit line structures 370 may be within the second cavity 335 and between the separation regions 382-a, 382-b, and 382-c, as described and illustrated with reference to FIG. 3I.

As illustrated in FIG. 3J, the plug 353 may be a rectangular prism or other cubic or rectangular shape that extends in the y-direction (e.g., horizontally) within a trench formed by the first cavity 337 in the first level of the stack of materials 305. The plug 353 may have a first thickness in the x-direction and a second thickness in the z-direction, where the first and second thicknesses may be the same or different. The plug 353 may provide a continuous and solid base connection point for each of the bit line structures 370, which may protect against a source material being diffused throughout the memory architecture 300-j. The bit line structures 370 may be in direct physical contact with the plug 353 at a base contact region 371, and may otherwise be separated from one another. For example, the bit line structure 370-a may not be in direct physical contact with the bit line structures 370-b or 370-c.

As illustrated in FIG. 3J, the bit line structures 370 may be formed in between the separation regions 382, such that each separation region 382 may separate at least two bit line structures 370 from one another in the y-direction. The bit line structures 370 may each extend horizontally in the x-direction from the top surface of the plug 353 to sidewalls of the second cavity 335 and may extend vertically in the z-direction within the stack of materials 305 and along sidewalls of the second cavity 335. The bit line structures 370 may be configured as bit lines that may active or select one or more memory cells within the stack (e.g., memory cell pillars) or as conductive channels (e.g., strings) between memory cells 105 connected in series, as described inf further detail elsewhere herein, including with reference to FIG. 2H. In some examples, each of the bit line structures 370 illustrated in FIG. 3J may include or otherwise be coupled with one or more bit lines. For example, each bit line structure 370 may include a first portion on a first side (e.g., in the x-direction) of the plug 353 and a second portion on a second side (e.g., in the x-direction) of the plug 353, where the first and second portions are in contact at the base contact region 371. Each portion may be coupled with a respective bit line, in some examples.

The separation material 380 may thereby provide for improved reliability and reduced interference during a backside source formation. For example, because the conductive material 350 is deposited underneath the separation regions 382, the conductive material 350 is not etched in those regions, which may improve an interface of the plug 353 and may reduce electron trap, among other benefits.

FIG. 3K illustrates an example of a memory architecture 300-k in accordance with a birds-eye view after the sixth processing step as described with reference to FIGS. 3I and 3J. The memory architecture 300-k may represent the memory architectures 300-i and 300-j from the birds-eye or top-down view (e.g., in the xy-plane).

The memory architecture 300-k illustrates how, the second protective liner 340 in the separation regions 382 is planar with the conductive material 350 in the regions in between the separation regions 382 in the x-direction. That is, the second cavity 335 has a continuous thickness or width 338 along the y-direction.

After the separation material 380 is formed in the discrete separation regions 382, the storage material 390 is formed over the separation material 380. The storage material 390 forms along the exposed sidewalls of each segment of the separation material 380 and along the sidewalls of the first protective liner 345 in between the segments of separation material 380, thereby forming a shape that alternatives from extending in the x-direction to the y-direction and back in the x-direction, and so on. The second protective liner 340 is formed on top of the storage material 390 in a similar structure. The conductive material 350 is then formed within the cavities that are left between each separation region 382. For example, there may be a cavity with three sidewalls of the second protective liner 340, and the conductive material 350 may be formed as a rectangular prism within those cavities and extending in the z-direction until the conductive material 350 reaches the plug 353 described with referenced to FIGS. 3I and 3J. The conductive material 350 may thereby form the separated bit line structures, such as the bit line structures 370 as described with reference to FIG. 3J.

FIG. 3L illustrates an example of a memory architecture 300-l after the sixth processing step described herein. The memory architecture 300-l may be a separate cross-sectional view of the same apparatus as that illustrated in FIG. 3K. For example, the memory architecture 300-l illustrates a cross-sectional view of the memory architecture 300-i when cut across the C-C′ and D-D′ cross-sectional lines, as illustrated in FIG. 3I.

The memory architecture 300-l illustrates a birds-eye or top-down view of the memory architecture 300-i at the C-C′ and D-D′ cross-sections, which generally cut through the recess 336 between the first level 310 and the second level 315 of the stack of materials 305. The memory architecture 300-l includes, at the C-C′ cross-sectional area, the conductive material 350 extending through to the bottom surface of the second cavity 335, the second protective liner 340 extending along the bottom surface of the second cavity 335, and the storage material 390 formed as a rectangular liner that surrounds the second protective liner 340. The storage material 390 may be in contact with the first protective liner 345 on either side in the x-direction. The oxide material 303 may extend along the outside of the structure (e.g., as the cross-sectional lines C-C′ and D-D′ are within a layer of the oxide material 303).

The memory architecture 300-l further includes, at the D-D′ cross-sectional area, the separation material 380 extending over the x-direction between the protective liner 345 and the oxide material 303 on either side. The regions of conductive material 350 and separation material 380 may further alternate along the y-direction to separate the bit line structures.

FIG. 3M illustrates an example of a memory architecture 300-m after the sixth processing step described herein. The memory architecture 300-m may be a separate cross-sectional view of the same apparatus as that illustrated in FIGS. 3K and 3L. For example, the memory architecture 300-m illustrates a cross-sectional view of the memory architecture 300-i when cut across the E-E′ and F-F′ cross-sectional lines, as illustrated in FIG. 3I.

The memory architecture 300-m illustrates a birds-eye or top-down view of the memory architecture 300-i at the E-E′ and F-F′ cross-sections, which generally cut through the recess 336 between the first level 310 and the second level 315 of the stack of materials 305. The memory architecture 300-m is generally the same at both the E-E′ and F-F′ cross-sectional areas. That is, within the first cavity and the first level 310, there may not be a change in materials across the y-direction.

The memory architecture 300-m may include two sets of material segments, each set including the sacrificial material 302, the liner of sacrificial material 330, the first protective liner 345, the storage material 390, and the second protective liner 340. The materials may extend in the y-direction and may have varying thicknesses in the x-direction. The two sets of materials may be sandwiched together with the conductive material 350 (e.g., the plug 353) in between in the x-direction.

FIG. 3N illustrates an example of a memory architecture 300-n after a seventh processing step associated with metallization and backside source formation. The memory architecture 300-n illustrates cross-sectional views along the A-A′, B-B′, C-C′, D-D′, E-E′, and F-F′ cross-sectional lines as described with reference to FIGS. 3I through 3M.

As part of the seventh processing step, a metallization process may be performed to convert the sacrificial material 302 to the metal material 304. The stack of materials 305 may thereby include layers of the oxide material 303 and layers of the metal material 304. The metallization may not alter the structure of the first protective liner 345, the second protective liner 340, the storage material 390, the plug 353, the conductive material 350, the separation material 380, or the channel oxide material 355. The plug 353 may have a thickness 354.

The seventh processing step may further include a backside source formation process, in which the source 360 is formed. In some examples, a substrate may be positioned beneath the memory architecture 300-i illustrated in FIG. 3I. As part of the backside source formation, the apparatus may be flipped or otherwise rotated and the substrate may be removed such that the manufacturing system may access a “backside” of the apparatus, which may correspond to a bottom of the first level 310 of the stack of materials 305.

A source material may be deposited from the backside of the apparatus to form the source 360. The source material may include an n+poly-silicon material, some other material, or any combination thereof. The source material deposition may, in some examples, result in phosphorous diffusion, which may degrade a portion of the plug 353 (e.g., in the vertical or z-direction), but may not degrade or otherwise remove all of the plug 353 due to the plug 353 having sufficient thickness 354. As such, the plug 353 may remain during the backside source formation and the source 360 may be in contact with the plug 353 across the entire or most of the thickness 354 (e.g., over a full surface of the plug 353). The source 360 may thereby be formed without any materials entering the second cavity 335 or other unintended areas of the apparatus. Because the plug 353 extends along the y-direction, even in the separation regions 382 of the apparatus, the entire structure is protected from the backside source diffusion, including those areas (e.g., the separation regions 382) that do not include bit line structures. For example, as illustrated in the B-B′ cross-sectional view of the memory architecture 300-n, the second cavity 335 may not include any of the source material after the formation of the source 360 because the plug 353 may stop the diffusion of the source material elsewhere in the structure.

The layers of metal material 304 may be word lines configured to access memory cells 105-f, 105-g, and 105-h within the respective layer. For example, a memory cell 105 may be formed at each junction of the storage material 390 with a respective layer of the metal material 304 and a respective bit line structure including the conductive material 350. The memory cells 105-f, 105-g, and 105-g illustrated in FIG. 3N may be included in a memory cell pillar, in some examples. Although not illustrated, it is to be understood that three more memory cells 105 may be included in the other side of the A-A′ cross-sectional view of the memory architecture 300-n.

A given memory cell 105 may be accessed by activation of both a corresponding word line and a corresponding bit line structure at the same time. The activation of the word lines (e.g., the metal material 304) may be controlled via one or more word line decoders or other circuitry, which may be positioned under the array (e.g., within a substrate or elsewhere in the memory architecture 300-n). The activation of the bit line structures may be controlled via a transistor or other selection circuitry, which may include the plug 353, the source 360, and the selector 365. For example, a voltage may be applied via the source 360, and the voltage that passes through to the plug 353 and corresponding bit line structures may be controlled by the selector 365 (e.g., a gate, an electrode). The voltage may be referred to as a threshold voltage, in some examples. The selector 365 may be relatively close to the source 360 (e.g., closer than the other layers of the metal material 304 to the n+ diffusion point), which may provide for more accurate and reliable control of the threshold voltage (e.g., a gate-source voltage) and corresponding current through the conductive material 350 than if the selector 365 is positioned a further distance from the source 360.

FIG. 3O illustrates an example of a memory architecture 300-o after the seventh processing step described herein. The memory architecture 300-o illustrates the memory architecture 300-n from a trimetric viewpoint. That is, a portion of the architecture in the y-direction is further shown in FIG. 3O to further illustrate the bit line structures 370 (e.g., bit line structures 370-a, 370-b, 370-c, and 370-d) and the spacing between them in more detail than shown in the previous figures. Bit line structures 370-a, 370-b, 370-c, and 370-d may represent examples of the corresponding bit line structures illustrated in FIG. 3J once formed in between respective separation regions 382.

The source 360 may be formed across a bottom of the structure and may be in contact with a surface of the plug 353 in the x- and y-directions. The selector 365 may include the metal material 304 and may extend along the x- and y-directions around the plug 353. That is, the first protective liner 345, the second protective liner 340, and the storage material 390 may be positioned on each side of the plug 353 between the plug 353 and the selector 365. The protective liners 345 and 340, as well as the storage material 390, may continue to extend vertically through the stack. Multiple memory cells 105 may be formed at junctions of the storage material 390, the word lines (e.g., the layers of the metal material 304) and the bit line structures 370, as described and illustrated in FIG. 3N.

The bit line structures 370 may represent rectangular or curved U-shaped segments that extend from the plug 353. For example, each bit line structure 370 may be in contact with (e.g., coupled with) the plug 353 at a respective base contact region 371. The bit line structure 370 may extend horizontally on each side of the base contact region 371. The bit line structure 370 may extend vertically from the horizontal segment and along sidewalls of the stack of materials including the oxide material 303 and the metal material 304 (e.g., word lines), as described with reference to FIG. 3J. In some examples, a channel oxide material 355 may be positioned on top of the bit line structures 370.

Each bit line structure 370 may be physically separated from (e.g., independent from, not in contact with) each other bit line structure 370. For example, the bit line structure 370-c may not be in direct contact with the bit line structure 370-b or the bit line structure 370-d, or any other bit line structures 370 outside of the base contact regions 371 at which each of the bit line structures 370 contacts the plug 353. In some examples, a region where a bit line structure 370 extends vertically along the second protective liner 340 and corresponding storage material 390 may be referred to as a memory cell pillar, as there may be multiple memory cells 105 stacked in that area (e.g., at each layer of the metal material 304).

In this example, each bit line structure 370 may be adjacent to at least one separation region 382. The separation regions 382 may include the separation material 380 as well as portions of the second protective liner 340 and the storage material 390 that at least partially surround the separation material 380 (e.g., on three sides of the separation material 380). The second protective liner 340 and the storage material 390 and further extend along a sidewall of the first protective liner 345 between each of the separation regions 382 and may be positioned between the conductive material and corresponding bit line structures 370 and the first protective liner 345.

As described with reference to FIG. 3N, the selector 365 may be configured to adjust, based on a voltage applied to the selector 365, a current that flows through the plug 353 and corresponding bit line structures 370 from the source 360. The apparatus may thereby select one or more memory cells 105 by activating, using the source 360 and the selector 365, the bit line structures 370, and activating one or more of the word lines (e.g., the layers of the metal material 304) that are at the same level as the target memory cell(s) 105.

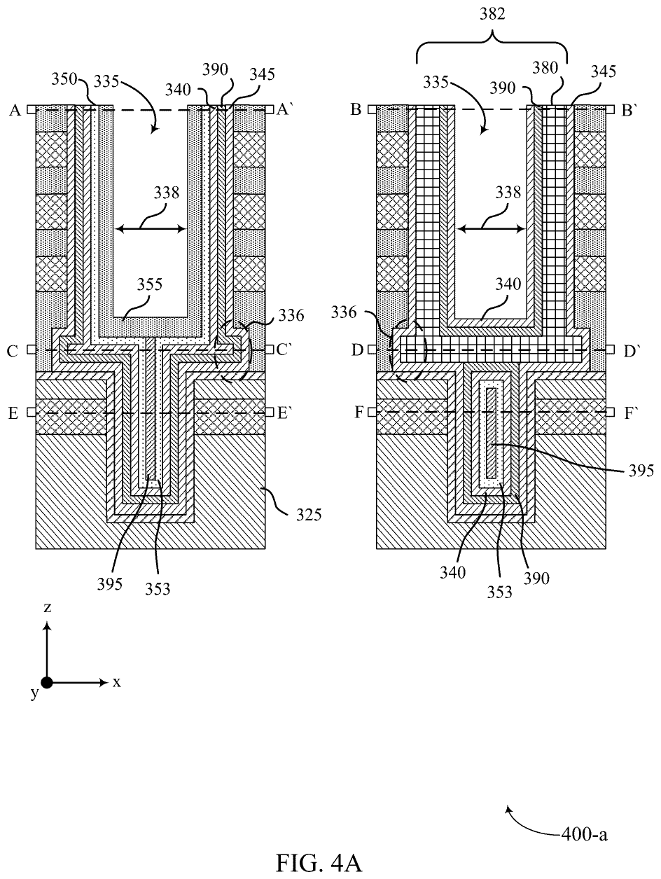

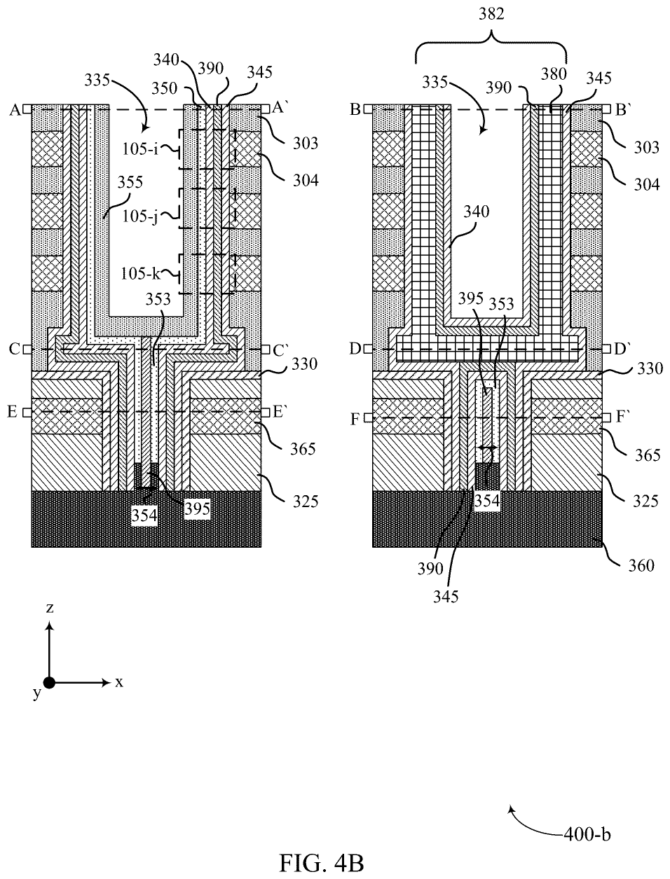

FIGS. 4A and 4B show examples of memory architectures 400 after various processing steps that support formation of a plug for protection of backside source formation of vertical planar memory cells in accordance with examples as disclosed herein. The memory architecture 400 may be an example of a portion of an apparatus, such as an apparatus 100. FIGS. 4A and 4B show planar views of the memory architecture 400, which may be an example of a memory architecture implemented by an apparatus 100, as described with reference to FIG. 1. The memory architectures 400 may illustrate operations associated with forming an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, the memory architectures 400-a and 400-b illustrate the memory architecture with a cross-sectional and/or planar view, such that a portion of the memory architecture may be removed from a trimetric view (e.g., as described with reference to FIG. 3O, among other sections) to illustrate a cross-section of the memory architecture in the xz-plane. Although the memory architectures 400 illustrate examples of relative dimensions and quantities of various features, aspects of the memory architectures 400 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 4A and 4B may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

In some examples, the first through sixth processing steps described with reference to FIGS. 3A through 3I may be performed prior to the next processing step described with reference to FIG. 4A.

FIG. 4A illustrates an example of a memory architecture 400-a after a seventh processing step in which an oxide pillar 395 is formed. The memory architecture 400-a illustrates a horizontal view, as illustrated by the memory architecture 300-i. This view corresponds to the memory architectures 300-g and 300-h after the sixth and seventh processing steps are formed and as cut along the A-A′ and B-B′ cross-sectional lines.

The memory architecture 400-a may include all of the various materials and structures as described in further detail with reference to FIG. 3I, but may include an additional oxide pillar 395. For example, after the conductive material 350 is deposited in the second cavity 335 and the first cavity 337, at least a portion of the conductive material 350 may be etched or otherwise removed to form a cavity within the conductive material. The cavity may correspond to an opening under the separation regions 382 and an opening in the central region of the conductive material 350 that is exposed to the second cavity 335 in between the separation regions 382. The cavity may subsequently be filled with an oxide material to form the oxide pillar 395, which may fill a center of the conductive plug 353. The channel oxide material 355 may be formed before or after the oxide pillar 395 is formed.

The inclusion of the oxide pillar 395 within the conductive plug 353 may suppress cracking due to migration of poly-silicon materials. The oxide may suppress cracking due to warpage by crystallization of amorphous silicon, and may thereby increase a string current.

FIG. 4B illustrates an example of a memory architecture 400-b after an eighth processing step associated with metallization and backside source formation. The memory architecture 400-b illustrates cross-sectional views along the A-A′, B-B′, C-C′, D-D′, E-E′, and F-F′ cross-sectional lines as described with reference to FIGS. 3I and 4A.

As part of the eighth processing step, a metallization process may be performed to convert the sacrificial material 302 to the metal material 304. The stack of materials 305 may thereby include layers of the oxide material 303 and layers of the metal material 304. The eighth processing step may further include a backside source formation process, in which the source 360 is formed. The metallization and source formation processes are described in further detail elsewhere herein, including with reference to FIG. 3N.

The source material deposition may, in some examples, result in phosphorous diffusion, which may degrade a portion of the plug 353 and/or the oxide pillar 395 (e.g., in the vertical or z-direction), but may not degrade or otherwise remove all of the plug 353 due to the plug 353 having sufficient thickness 354 (e.g., based on the oxide pillar 395). As such, the plug 353 may remain during the backside source formation and the source 360 may be in contact with the plug 353 across the entire or most of the thickness 354 (e.g., over a full surface of the plug 353). The source 360 may thereby be formed without any materials entering the second cavity 335 or other unintended areas of the apparatus. Because the plug 353 and oxide pillar 395 extend along the y-direction, even in the separation regions 382 of the apparatus, the entire structure is protected from the backside source diffusion, including those areas (e.g., the separation regions 382) that do not include bit line structures. For example, as illustrated in the B-B′ cross-sectional view of the memory architecture 300-n, the second cavity 335 may not include any of the source material after the formation of the source 360 because the plug 353 including the oxide pillar 395 may stop the diffusion of the source material elsewhere in the structure.

The layers of metal material 304 may be word lines configured to access memory cells 105-i, 105-j, and 105-k within the respective layer. For example, a memory cell 105 may be formed at each junction of the storage material 390 with a respective layer of the metal material 304 and a respective bit line structure including the conductive material 350. The memory cells 105-i, 105-j, and 105-k illustrated in FIG. 4B may be included in a memory cell pillar, in some examples. Although not illustrated, it is to be understood that three more memory cells 105 may be included in the other side of the A-A′ cross-sectional view of the memory architecture 400-b.

A given memory cell 105 may be accessed by activation of both a corresponding word line and a corresponding bit line structure at the same time. The activation of the word lines (e.g., the metal material 304) may be controlled via one or more word line decoders or other circuitry, which may be positioned under the array (e.g., within a substrate or elsewhere in the memory architecture 400-b). The activation of the bit line structures may be controlled via a transistor or other selection circuitry, which may include the plug 353, the source 360, and the selector 365. For example, a voltage may be applied via the source 360, and the voltage that passes through to the plug 353 and corresponding bit line structures may be controlled by the selector 365 (e.g., a gate, an electrode). The voltage may be referred to as a threshold voltage, in some examples. The selector 365 may be relatively close to the source 360 (e.g., closer than the other layers of the metal material 304 to the n+diffusion point), which may provide for more accurate and reliable control of the threshold voltage (e.g., a gate-source voltage) and corresponding current through the conductive material 350 than if the selector 365 is positioned a further distance from the source 360.

The inclusion of the oxide pillar 395 within the conductive plug 353 may thereby provide for improved protection of the memory architecture 400-b during source formation while reducing an amount of conductive material and reducing a likelihood of cracking during access operations, among other examples.

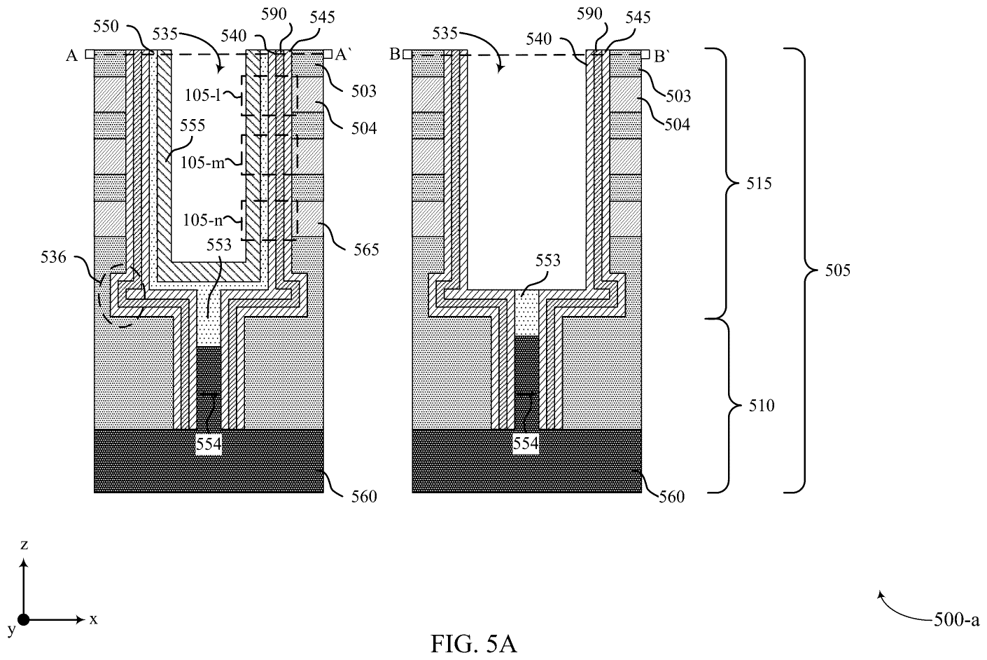

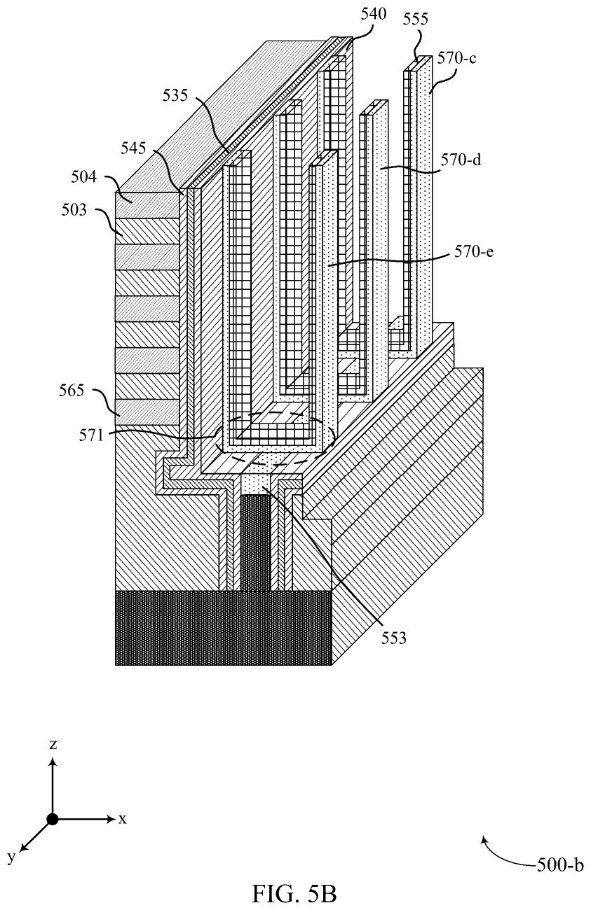

FIGS. 5A and 5B show examples of memory architectures 500 after various processing steps that support formation of a plug for protection of backside source formation of vertical planar memory cells in accordance with examples as disclosed herein. The memory architectures 500 may be an example of a portion of an apparatus, such as an apparatus 100. FIGS. 5A and 5B show various views (e.g., diagonal or trimetric views, planar views, other views) of a memory architecture 500, which may be an example of a memory architecture implemented by an apparatus 100, as described with reference to FIG. 1. The memory architectures 500 may illustrate operations associated with forming an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, memory architecture 500-b illustrates the memory architecture from trimetric views, where a substrate of the memory architecture may be associated with an xy-plane, and where the memory architecture extends a distance along the z-direction. Additionally, the memory architecture 500-a may illustrate the memory architecture with a cross-sectional and/or planar view, such that a portion of the memory architecture may be removed from the trimetric view to illustrate a cross-section of the memory architecture in the xz-plane, the xy-plane, or both. Although the memory architectures 500 illustrate examples of relative dimensions and quantities of various features, aspects of the memory architectures 500 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Process steps illustrated in and described with reference to FIGS. 5A and 5B may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 5A illustrates an example of a memory architecture 500-a after four processing steps associated with forming a stack of materials 505. The four processing steps may represent examples of the four processing steps described with reference to FIGS. 2A through 2H. For example, a first processing step may include forming the stack of materials 505 and a sacrificial plug. Forming the stack of materials 505 may include depositing alternating (e.g., or at least partially alternating) layers of an oxide material 503 and a sacrificial material above a substrate (e.g., a plane or sheet in the xy-plane on which subsequent memory materials may be formed. The substrate may be associated with CMOS circuitry. In some such examples, depositing the alternating layers may include depositing a layer of the oxide material 503, then depositing a layer of the sacrificial material above the layer of the oxide material 503. Accordingly, the sacrificial material and the oxide material 503 may be similarly deposited to form alternating layers, where the height of the stack of materials 505 may be based on the quantity and height of each of the alternating layers. In some implementations, the oxide material 503 may be a dielectric material, such as silicon oxide, silicon oxycarbide, silicon oxynitride, or silicon nitride. In some implementations, the sacrificial material may be a variation of nitride.

In some examples, the stack of materials 505 may be formed in two or more formation processes. For example, the first level 510 may be formed first, and the second level 515 may be formed after formation of the first level 510. In the example of FIG. 5A, the first level 510 may be formed without any of the sacrificial material. That is, the first level 510 may be formed by depositing the oxide material 503.

In some examples, after the first level 510 is formed, the first level 510 may be etched to form a first cavity (not pictured in FIG. 5A) having a first width. The first cavity may pass through the first level 510 of the stack of materials 505 in a first direction (e.g., vertical, the z-direction) and a second direction (e.g., horizontal, the y-direction). The first cavity may not extend fully through the first level 510, such that a portion of oxide material 503 may remain between the first cavity and a substrate, in some examples. The first cavity may be filled with a sacrificial material. The second level 515 may then be formed on top of the first level 510 including the cavity filled with the sacrificial material.

After forming the second level 515 of the stack of materials 505, one or more other cavities may be formed. For example, a second cavity 535 may be formed in the second level 515 of the stack of materials 505. The second cavity 535 may be above the first cavity relative to the substrate. The second cavity 535 may pass through the second level 515 of the stack of materials 505 in the first direction (e.g., the z-direction) and the second direction (e.g., the y-direction). The first cavity and the second cavity 535 may be formed via respective etch processes in which materials are removed from the stack of materials 505 to form the cavities. The first cavity may be formed with a first width and the second cavity 535 may be formed with a second width, where the second width is greater than the first width.

In some examples, a recess 536 may be formed within the stack of materials 505 between the first cavity and the second cavity 535. For example, a portion of the oxide material 503 in the second level 515 of the stack of materials 505 may be etched to form a recess 536 (e.g., on each side of the stack) that expands a width of the second cavity 535 from the second width to a third width that is greater than the first width and the second width.

After forming the stack of materials 505 and the various cavities, a sacrificial plug may be formed within the first cavity and the recess 536, as described and illustrated in FIG. 2A. The sacrificial plug may subsequently be removed (e.g., etched, exhumed) from the stack of materials 505, and one or more layers of materials may be deposited or formed within the first cavity, the recess 536, and the second cavity 535 after the sacrificial plug is removed. The layers of materials may include, for example, a first protective liner 545, a storage material 590, and a second protective liner 540. The materials may be deposited and subsequently etched back to form liners that extend along sidewalls of the stack of materials 505. For example, the first protective liner 545 may extend along sidewalls of the stack of materials 505 within the first cavity, within the recess 536, and within the second cavity 535. The storage material 590 may extend along the first protective liner 545 and between the first protective liner 545 and the second protective liner 540. In some examples, the second protective liner 540 may be deposited and subsequently etched such that a shape of the second protective liner 540 may generally be a U-shape within the second level 515. That is, the second protective liner 540 may include, in some examples, fewer (e.g., or none) curves within the recess 536 than the first protective liner 545 and/or the storage material 590.

After the first protective liner 545, the storage material 590, and the second protective liner 540 are formed, a conductive material 550 may be formed (e.g., deposited) over the second protective liner 540 within a remainder of the first cavity and a portion of the second cavity 535. The conductive material 550 may be associated with one or more bit line structures of the apparatus. A size of the second cavity 535 after these depositions of materials may be reduced. The conductive material 550 may thereby fill the first cavity, such that the first level 510 is filled with materials. The conductive material 550 may, in some examples, be formed in the shape of a football field goal post, or a rectangular U-shape connected to a vertical post.

A channel oxide material 555 may be deposited within the second cavity 535. The channel oxide material 555 may be formed on top of the conductive material 550 and may be formed with a threshold thickness or may be etched back, such that the channel oxide material 555 has a relatively constant thickness within the second cavity 535. In some examples, the formation of the channel oxide material 555 may reduce a thickness of the conductive material 550 within the second cavity 535.

The conductive material 550 and the channel oxide material 555 may be etched. The etching may be performed using a mask, which may cover some portions of the stack of materials and expose other portions. The conductive material 550 and the channel oxide material 555 within the exposed portions may be removed (e.g., etched, exhumed, or the like). There may be remaining segments of conductive material 550 within the second cavity 535 (e.g., a trench). The conductive material 550 may be etched such that each segment of conductive material is separated from (e.g., not in direct physical contact with) any other segment of the conductive material within the second level 515 of the stack. The channel oxide material 555 may be etched to a similar or the same shape as the conductive material 550. In some examples, the channel oxide material 555 may be formed on top of the conductive material 550 after the etching. Additionally, or alternatively, the channel oxide material 555 may be formed prior to the etching.

After formation of the channel oxide material 555 and corresponding etching, a metallization process may be performed to convert the sacrificial material to the metal material 504. The stack of materials may thereby include layers of the oxide material 503 and layers of the metal material 504. The metallization may not alter the structure of the other materials in the stack of materials 505. The fourth processing step may further include a backside source formation process, in which the source 560 is formed.

A source material may be deposited from the backside of the apparatus to form the source 560. The source material may include an n+ poly-silicon material, some other material, or any combination thereof. The source material deposition may, in some examples, result in phosphorous diffusion, which may degrade a portion of the plug 553 (e.g., in the vertical or z-direction), but may not degrade or otherwise remove all of the plug 553 due to the plug 553 having sufficient thickness 554. As such, the plug 553 may remain during the backside source formation and the source 560 may be in contact with the plug 553 across the entire or most of the thickness 554 (e.g., over a full surface of the plug 553). The source 560 may thereby be formed without any materials entering the second cavity 535 or other unintended areas of the apparatus. Because the plug 553 extends along the y-direction, even in regions of the apparatus where the bit line structures were removed due to etching, the entire structure is protected from the backside source diffusion, including those areas that do not include bit line structures. For example, as illustrated in the B-B′ cross-sectional view of the memory architecture 500-a, the second cavity 535 may not include any of the source material after the formation of the source 560 because the plug 553 may stop the diffusion of the source material elsewhere in the structure.

The layers of metal material 504 may be word lines configured to access memory cells 105-l, 105-m, and 105-n within the respective layer. For example, a memory cell 105 may be formed at each junction of the storage material 590 with a respective layer of the metal material 504 and a respective bit line structure including the conductive material 250. The memory cells 105-l, 105-m, and 105-n illustrated in FIG. 5A may be included in a memory cell pillar, in some examples, along with a corresponding bit line structure (e.g., the conductive material 250). Although not illustrated, it is to be understood that three more memory cells 105 may be included in the other side of the A-A′ cross-sectional view of the memory architecture 500-a.

A given memory cell 105 may be accessed by activation of both a corresponding word line and a corresponding bit line structure at the same time. The activation of the word lines (e.g., the metal material 504) may be controlled via one or more word line decoders or other circuitry, which may be positioned under the array (e.g., within a substrate or elsewhere in the memory architecture 500-a). The activation of the bit line structures may be controlled via a transistor or other selection circuitry, which may include the plug 553, the source 560, and the selector 565. The selector 565 may be one of the word lines within the second level 515 of the stack of materials 505 that is operable to apply a voltage to the bit line structures (e.g., a string selector). For example, a voltage may be applied via the source 560, and the voltage that passes through to the plug 553 and corresponding bit line structures may be controlled by the selector 565 (e.g., a gate, an electrode). The voltage may be referred to as a threshold voltage, in some examples.

As described herein, the first level 510 of the stack of materials 505 may not include any metal material 504. Thus, the selector 565 may not be included in the first level 510. The inclusion of the selector 565 in the second level 515 may reduce formation complexity and material costs, among other examples, but may increase a break down voltage between the selector 565 (e.g., a select gate source (SGS)) and the source 560. The voltage applied by the selector 565 may be controlled in the same conductive material 550 as the memory cell 105, which may improve subthreshold slope.

FIG. 5B illustrates an example of a memory architecture 500-b after the fourth processing step described herein. The memory architecture 500-b illustrates the memory architecture 500-a from a trimetric viewpoint. That is, a portion of the architecture in the y-direction is further shown in FIG. 5B to further illustrate the bit line structures 570 (e.g., bit line structures 570-c, 570-d, and 570-e) and the spacing between them in more detail than shown in the previous figures.

The source 560 may be formed across a bottom of the structure and may be in contact with a surface of the plug 553 in the x- and y-directions. The first protective liner 545, the second protective liner 540, and the storage material 590 may be positioned on each side of the plug 553 between the plug 553 and the oxide material 503 in the first level 510 of the stack of materials 505. The protective liners 545 and 540, as well as the storage material 590, may continue to extend vertically through the stack. Multiple memory cells 105 may be formed at junctions of the storage material 590, the word lines (e.g., the layers of the metal material 504) and the bit line structures 570, as described and illustrated in FIG. 5A.

The bit line structures 570 may represent rectangular or curved U-shaped segments that extend from the plug 553. For example, each bit line structure 570 may be in contact with (e.g., coupled with) the plug 553 at a respective base contact region 571. The bit line structure 570 may extend horizontally on each side of the base contact region 571. The bit line structure 570 may extend vertically from the horizontal segments on each side of the base contact region 571 and along sidewalls of the stack of materials including the oxide material 503 and the metal material 504 (e.g., word lines). In some examples, a channel oxide material 555 may be positioned on top of the bit line structures 570. Each bit line structure 570 may be physically separated from (e.g., independent from, not in contact with) each other bit line structure 570. For example, the bit line structure 570-c may not be in direct contact with the bit line structure 570-d or the bit line structure 570-e outside of the base contact regions 571 at which each of the bit line structures 570 contacts the plug 553. In some examples, a region where a bit line structure 570 extends vertically along the second protective liner 540 and corresponding storage material 590 may be referred to as a memory cell pillar, as there may be multiple memory cells 105 stacked in that area (e.g., at each layer of the metal material 504).

As described with reference to FIG. 5A, the selector 565 may be positioned in the second level 515 of the stack of materials 505 (e.g., above the recess 536 and parallel to a portion of the bit line structures 570. The selector 565 may be configured to adjust, based on a voltage applied to the selector 565, a current that flows through the plug 553 and corresponding bit line structures 570 from the source 560. The apparatus may thereby select one or more memory cells 105 by activating, using the source 560 and the selector 565, the bit line structures 570-c, 570-d, and 570-c, and activating one or more of the word lines (e.g., the layers of the metal material 504) that are at the same level as the target memory cell(s) 105.

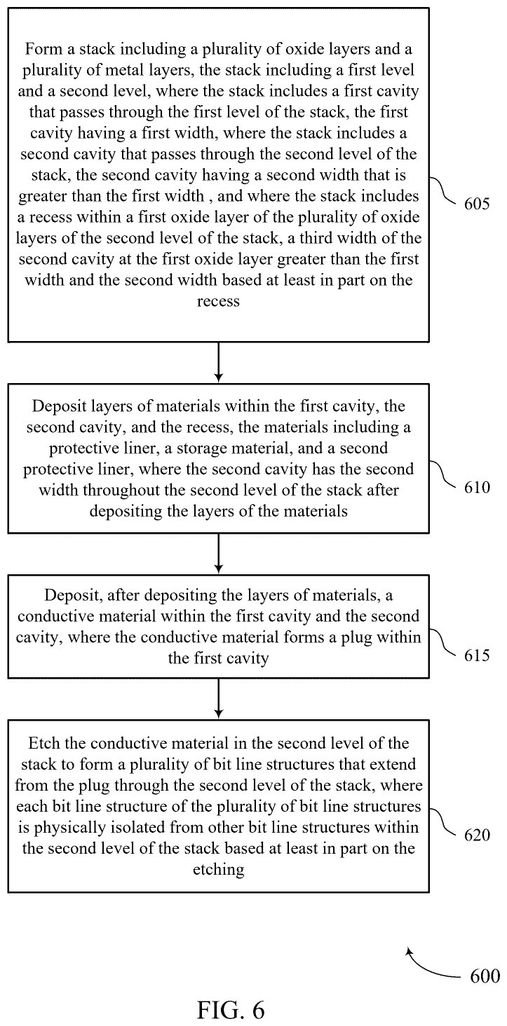

FIG. 6 shows a flowchart illustrating a method 600 that supports formation of an apparatus including a plug for protection of backside source formation of vertical planar memory cells in accordance with examples as disclosed herein. The operations of method 600 may be implemented by a manufacturing system or its components as described herein. For example, the operations of method 600 may be performed by a manufacturing system as described with reference to FIGS. 1 through 5B. In some examples, a manufacturing system may execute a set of instructions to control the functional elements of the device to perform the described functions. Additionally, or alternatively, the manufacturing system may perform aspects of the described functions using special-purpose hardware.

At 605, the method may include forming a stack including a plurality of oxide layers and a plurality of metal layers, the stack including a first level and a second level, where the stack includes a first cavity that passes through the first level of the stack, the first cavity having a first width, where the stack includes a second cavity that passes through the second level of the stack, the second cavity having a second width that is greater than the first width, and where the stack includes a recess within a first oxide layer of the plurality of oxide layers of the second level of the stack, a third width of the second cavity at the first oxide layer greater than the first width and the second width based at least in part on the recess.

At 610, the method may include depositing layers of materials within the first cavity, the second cavity, and the recess, the materials including a protective liner, a storage material, and a second protective liner, where the second cavity has the second width throughout the second level of the stack after depositing the layers of the materials.

At 615, the method may include depositing, after depositing the layers of materials, a conductive material within the first cavity and the second cavity, where the conductive material forms a plug within the first cavity.

At 620, the method may include etching the conductive material in the second level of the stack to form a plurality of bit line structures that extend from the plug through the second level of the stack, where each bit line structure of the plurality of bit line structures is physically isolated from other bit line structures within the second level of the stack based at least in part on the etching.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a stack including a plurality of oxide layers and a plurality of metal layers, the stack including a first level and a second level, where the stack includes a first cavity that passes through the first level of the stack, the first cavity having a first width, where the stack includes a second cavity that passes through the second level of the stack, the second cavity having a second width that is greater than the first width, and where the stack includes a recess within a first oxide layer of the plurality of oxide layers of the second level of the stack, a third width of the second cavity at the first oxide layer greater than the first width and the second width based at least in part on the recess; depositing layers of materials within the first cavity, the second cavity, and the recess, the materials including a protective liner, a storage material, and a second protective liner, where the second cavity has the second width throughout the second level of the stack after depositing the layers of the materials; depositing, after depositing the layers of materials, a conductive material within the first cavity and the second cavity, where the conductive material forms a plug within the first cavity; and etching the conductive material in the second level of the stack to form a plurality of bit line structures that extend from the plug through the second level of the stack, where each bit line of the plurality of bit line structures is physically isolated from other bit line structures within the second level of the stack based at least in part on the etching.

Aspect 2: The method, apparatus, or non-transitory computer-readable medium of aspect 1, further including operations, features, circuitry, logic, means, or instructions, or any combination thereof for etching, as part of a backside formation, one or more layers in the first level of the stack and at least a portion of the plug, where the etching forms a third cavity within the one or more layers and the portion of the plug and depositing, after etching the one or more layers, a source material within the third cavity to form a source for accessing a plurality of memory cells, where a remainder of the plug blocks the source material from entering remaining portions of the stack.

Aspect 3: The method, apparatus, or non-transitory computer-readable medium of any of aspects 1 through 2, where etching the conductive material includes operations, features, circuitry, logic, means, or instructions, or any combination thereof for etching, based at least in part on a mask, alternating regions of the conductive material to form a plurality of U-shaped strips of the conductive material that extend along the bottom of the second cavity, the first sidewall of the second cavity, and the second sidewall of the second cavity, and where each U-shaped strip of the plurality of U-shaped strips is in contact with the plug in the first level of the stack and is physically isolated from other U-shaped strips of the plurality of U-shaped strips within the second level of the stack by respective spaces based at least in part on the etching.

Aspect 4: The method, apparatus, or non-transitory computer-readable medium of any of aspects 1 through 3, further including operations, features, circuitry, logic, means, or instructions, or any combination thereof for depositing, after depositing the conductive material, an oxide material within the second cavity, where etching the conductive material further includes etching the oxide material, and where the oxide material reduces a thickness of the conductive material within the second level of the stack.

Aspect 5: The method, apparatus, or non-transitory computer-readable medium of any of aspects 1 through 4, where forming the first level of the stack includes operations, features, circuitry, logic, means, or instructions, or any combination thereof for depositing at least one oxide layer of the plurality of oxide layers; depositing at least one metal layer of the plurality of metal layers; and forming the first cavity that extends through the at least one oxide layer and the at least one metal layer, where the at least one metal layer is configured to activate the plurality of bit line structures.

Aspect 6: The method, apparatus, or non-transitory computer-readable medium of any of aspects 1 through 5, where forming the first level of the stack includes operations, features, circuitry, logic, means, or instructions, or any combination thereof for depositing a second oxide layer of the plurality of oxide layers and forming the first cavity that extends through the second oxide layer.

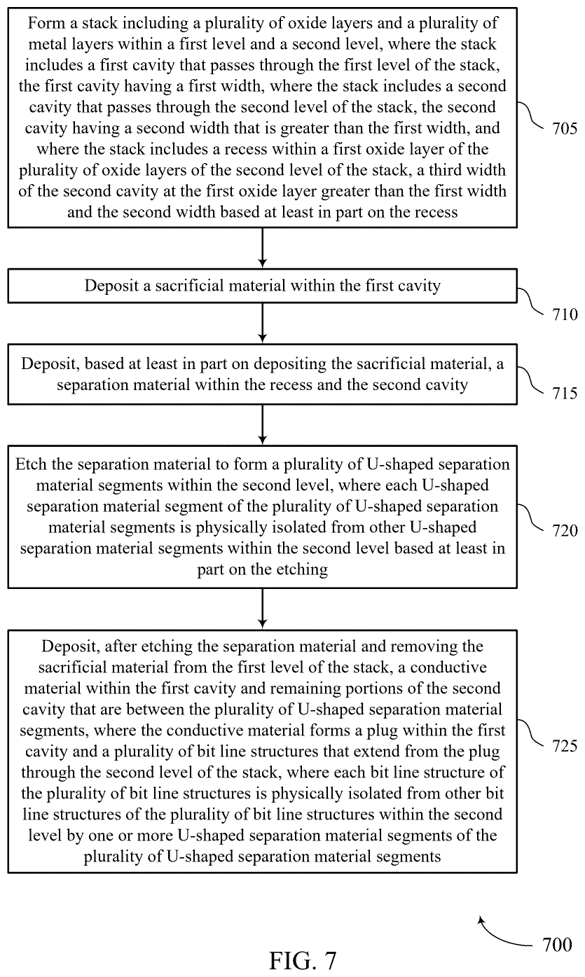

FIG. 7 shows a flowchart illustrating a method 700 that supports formation of an apparatus including a plug for protection of backside source formation of vertical planar memory cells in accordance with examples as disclosed herein. The operations of method 700 may be implemented by a manufacturing system or its components as described herein. For example, the operations of method 700 may be performed by a manufacturing system as described with reference to FIGS. 1 through 5B. In some examples, a manufacturing system may execute a set of instructions to control the functional elements of the device to perform the described functions. Additionally, or alternatively, the manufacturing system may perform aspects of the described functions using special-purpose hardware.

At 705, the method may include forming a stack including a plurality of oxide layers and a plurality of metal layers within a first level and a second level, where the stack includes a first cavity that passes through the first level of the stack, the first cavity having a first width, where the stack includes a second cavity that passes through the second level of the stack, the second cavity having a second width that is greater than the first width, and where the stack includes a recess within a first oxide layer of the plurality of oxide layers of the second level of the stack, a third width of the second cavity at the first oxide layer greater than the first width and the second width based at least in part on the recess.

At 710, the method may include depositing a sacrificial material within the first cavity.

At 715, the method may include depositing, based at least in part on depositing the sacrificial material, a separation material within the recess and the second cavity.

At 720, the method may include etching the separation material to form a plurality of U-shaped separation material segments within the second level, where each U-shaped separation material segment of the plurality of U-shaped separation material segments is physically isolated from other U-shaped separation material segments within the second level based at least in part on the etching.

At 725, the method may include depositing, after etching the separation material and removing the sacrificial material from the first level of the stack, a conductive material within the first cavity and remaining portions of the second cavity that are between the plurality of U-shaped separation material segments, where the conductive material forms a plug within the first cavity and a plurality of bit line structures that extend from the plug through the second level of the stack, where each bit line structure of the plurality of bit line structures is physically isolated from other bit line structures of the plurality of bit line structures within the second level by one or more U-shaped separation material segments of the plurality of U-shaped separation material segments.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 7: A method, apparatus, or non-transitory computer-readable medium including operations, features, circuitry, logic, means, or instructions, or any combination thereof for forming a stack including a plurality of oxide layers and a plurality of metal layers within a first level and a second level, where the stack includes a first cavity that passes through the first level of the stack, the first cavity having a first width, where the stack includes a second cavity that passes through the second level of the stack, the second cavity having a second width that is greater than the first width, and where the stack includes a recess within a first oxide layer of the plurality of oxide layers of the second level of the stack, a third width of the second cavity at the first oxide layer greater than the first width and the second width based at least in part on the recess; depositing a sacrificial material within the first cavity; depositing, based at least in part on depositing the sacrificial material, a separation material within the recess and the second cavity; etching the separation material to form a plurality of U-shaped separation material segments within the second level, where each U-shaped separation material segment of the plurality of U-shaped separation material segments is physically isolated from other U-shaped separation material segments within the second level based at least in part on the etching; and depositing, after etching the separation material and removing the sacrificial material from the first level of the stack, a conductive material within the first cavity and remaining portions of the second cavity that are between the plurality of U-shaped separation material segments, where the conductive material forms a plug within the first cavity and a plurality of bit line structures that extend from the plug through the second level of the stack, where each bit line structure of the plurality of bit line structures is physically isolated from other bit line structures of the plurality of bit line structures within the second level by one or more U-shaped separation material segments of the plurality of U-shaped separation material segments.

Aspect 8: The method, apparatus, or non-transitory computer-readable medium of aspect 7, where forming the first level of the stack includes operations, features, circuitry, logic, means, or instructions, or any combination thereof for depositing, after etching the separation material and removing the sacrificial material from the first level of the stack, a storage material within the first cavity and the second cavity, where; the storage material extends along at least three sidewalls of the first cavity; the storage material extends along at least three sidewalls of each U-shaped separation material segment of the plurality of U-shaped separation material segments within the second level of the stack; and the storage material extends along a sidewall of the stack between each of the plurality of U-shaped separation material segments.

Aspect 9: The method, apparatus, or non-transitory computer-readable medium of aspect 8, where depositing the conductive material includes operations, features, circuitry, logic, means, or instructions, or any combination thereof for depositing the conductive material after depositing the storage material, where the storage material extends between the sidewall of the stack and each bit line structure of the plurality of bit line structures based at least in part on depositing the conductive material.

Aspect 10: The method, apparatus, or non-transitory computer-readable medium of any of aspects 7 through 9, further including operations, features, circuitry, logic, means, or instructions, or any combination thereof for depositing, after depositing the conductive material, an oxide material within the first level of the stack, where the oxide material extends in a first direction within the plug based at least in part on depositing the oxide material.

Aspect 11: The method, apparatus, or non-transitory computer-readable medium of any of aspects 7 through 10, further including operations, features, circuitry, logic, means, or instructions, or any combination thereof for etching, as part of a backside source formation after depositing the conductive material, one or more layers in the first level of the stack and at least a portion of the plug, where the etching forms a third cavity within the one or more layers and the portion of the plug and depositing, after etching the one or more layers, a source material within the third cavity to form a source for accessing a plurality of memory cells, where a remainder of the plug and the separation material block the source material from entering remaining portions of the stack.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 12: An apparatus, including: a substrate; a stack including a plurality of oxide layers and a plurality of metal layers, the stack including a first level and a second level, the first level positioned between the substrate and the second level in a first direction; a plug passing through the first level of the stack in the first direction and extending in a second direction within the stack, the plug including a conductive material; a plurality of bit line structures including the conductive material and extending from the plug through the second level of the stack, where the plurality of bit line structures are distributed within the stack, and where each bit line structure of the plurality of bit line structures is coupled with the plug within a respective contact region and is physically isolated from other bit line structures of the plurality of bit line structures within other regions different from the contact region; and a plurality of memory cells positioned in the second level of the stack and between the plurality of metal layers and the plurality of bit line structures.

Aspect 13: The apparatus of aspect 12, further including: a plurality of separation regions between the plurality of bit line structures within the second level, where each pair of adjacent bit line structures is physically isolated from each other by a respective separation region of the plurality of separation regions, and where each separation region of the plurality of separation regions includes a separation material that extends between a respective pair of adjacent bit line structures in the first direction.

Aspect 14: The apparatus of aspect 13, further including: a storage material liner that extends between the plug and the stack in the first level where: the storage material liner extends in the second direction between the plurality of bit line structures and the stack in the second level; the separation material is positioned between the storage material liner and the stack within the plurality of separation regions; and the storage material liner extends in a third direction between each bit line structure of the plurality of bit line structures and an adjacent separation region of the plurality of separation regions.

Aspect 15: The apparatus of any of aspects 13 through 14, where in each separation region of the plurality of separation regions, a storage material liner is positioned between the plug in the first level of the stack and the separation material in the second level of the stack.

Aspect 16: The apparatus of any of aspects 12 through 15, where the plug includes a pillar of oxide material, the conductive material in contact with at least two sidewalls of the pillar of oxide material.

Aspect 17: The apparatus of any of aspects 12 through 16, further including: a plurality of oxide liners that each extend along a top surface of a respective bit line structure of the plurality of bit line structures.

Aspect 18: The apparatus of any of aspects 12 through 17, where the first level of the stack includes: a first selector within a first metal layer of the plurality of metal layers, the first selector configured to apply a voltage to the plurality of bit line structures via the plug.

Aspect 19: The apparatus of aspect 18 where the first level of the stack includes: the first metal layer of the plurality of metal layers positioned between two oxide layers of the plurality of oxide layers in the first direction.

Aspect 20: The apparatus of any of aspects 12 through 19, where the first level of the stack includes: a first oxide layer of the plurality of oxide layers, where the plurality of metal layers are within the second level of the stack.

Aspect 21: The apparatus of any of aspects 12 through 20, further including: a first channel that extends, in the first direction, through the first level of the stack, the first channel having a first width; a second channel that extends, in the first direction, through the second level of the stack, the second channel having a second width that is greater than the first width; and a junction region that is within the second level of the stack and between the first channel and the second channel, the junction region having a third width that is greater than the first width, where: the first channel includes one or more liners that extend along sidewalls of the first channel, the one or more liners positioned between the plug and the stack; the junction region includes the one or more liners and a portion of the plug; and the second channel includes the one or more liners that extend, in the first direction, along sidewalls of the second channel, the one or more liners positioned between the plurality of bit line structures and the stack.

Aspect 22: The apparatus of any of aspects 12 through 21, where the plurality of bit line structures includes a first subset of bit line structures and a second subset of bit line structures, the first subset of bit line structures including bit line structures that extend along a first axis in the second direction, and the second subset of bit line structures including bit line structures that extend along a second axis in the second direction, and the plug is between the first axis and the second axis in a third direction.

Aspect 23: The apparatus of any of aspects 12 through 22, where each bit line structure of the plurality of bit line structures includes a first segment and a second segment of the conductive material, the first segment extends, in a third direction, from a top surface of the plug to the second segment, and the second segment extends, in the first direction, from the first segment to a top layer of the stack.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a substrate;
a stack comprising a plurality of oxide layers and a plurality of metal layers, the stack comprising a first level and a second level, the first level positioned between the substrate and the second level in a first direction;
a plug extending through at least a portion of the first level of the stack in the first direction and extending in a second direction within the stack, the plug comprising a conductive material;
a plurality of bit line structures coupled with the plug and extending at least partially through the second level of the stack, wherein the plurality of bit line structures are distributed within the stack; and
a plurality of memory cells positioned in the second level of the stack, each memory cell of the plurality of memory cells positioned between a respective metal layer of the plurality of metal layers and a respective bit line structure of the plurality of bit line structures.

2. The apparatus of claim 1,, wherein the stack comprises first and second strings at least partially within the second level, the first string including a first selector including a first portion, and the second string including a second selector including a second portion, and wherein the plug is coupled with the first and second portions of the first and second selectors of the first and second strings.

3. The apparatus of claim 2, comprising:
an additional selector formed within the first level of the stack and including a gate surrounding the plug.

4. The apparatus of claim 1, wherein each bit line structure of the plurality of bit line structures is coupled with the plug within a respective contact region and is physically isolated from other bit line structures of the plurality of bit line structures within other regions different from the respective contact region.

5. The apparatus of claim 1, further comprising:
a plurality of separation regions between the plurality of bit line structures within the second level, wherein each pair of adjacent bit line structures is physically isolated from each other by a respective separation region of the plurality of separation regions, and wherein each separation region of the plurality of separation regions comprises a separation material that extends between a respective pair of adjacent bit line structures in the first direction.

6. The apparatus of claim 5, further comprising:
a storage material liner that extends between the plug and the stack in the first level, wherein:
the storage material liner extends in the second direction between the plurality of bit line structures and the stack in the second level;
the separation material is positioned between the storage material liner and the stack within the plurality of separation regions; and
the storage material liner extends in a third direction between each bit line of the plurality of bit line structures and an adjacent separation region of the plurality of separation regions.

7. The apparatus of claim 5, wherein, in each separation region of the plurality of separation regions, a storage material liner is positioned between the plug in the first level of the stack and the separation material in the second level of the stack.

8. The apparatus of claim 1, wherein the plug comprises a pillar of oxide material, the conductive material in contact with at least two sidewalls of the pillar of oxide material.

9. The apparatus of claim 1, further comprising:
a plurality of oxide liners that each extend along a top surface of a respective bit line of the plurality of bit line structures.

10. The apparatus of claim 1, wherein the first level of the stack comprises:
a first selector within a first metal layer of the plurality of metal layers, the first selector configured to apply a voltage to the plurality of bit line structures via the plug.

11. The apparatus of claim 10 wherein the first level of the stack comprises:
the first metal layer of the plurality of metal layers positioned between two oxide layers of the plurality of oxide layers in the first direction.

12. The apparatus of claim 1, wherein the first level of the stack comprises:
a first oxide layer of the plurality of oxide layers, wherein the plurality of metal layers are within the second level of the stack.

13. The apparatus of claim 1, further comprising:
a first channel that extends, in the first direction, through the first level of the stack, the first channel having a first width;
a second channel that extends, in the first direction, through the second level of the stack, the second channel having a second width that is greater than the first width; and
a junction region that is within the second level of the stack and between the first channel and the second channel, the junction region having a third width that is greater than the first width, wherein:
the first channel comprises one or more liners that extend along sidewalls of the first channel, the one or more liners positioned between the plug and the stack;
the junction region comprises the one or more liners and a portion of the plug; and
the second channel comprises the one or more liners that extend, in the first direction, along sidewalls of the second channel, the one or more liners positioned between the plurality of bit line structures and the stack.

14. The apparatus of claim 1, wherein:
the plurality of bit line structures comprises a first subset of bit line structures and a second subset of bit line structures, the first subset of bit line structures comprising bit line structures that extend along a first axis in the second direction, and the second subset of bit line structures comprising bit line structures that extend along a second axis in the second direction, and
the plug is between the first axis and the second axis in a third direction.

15. The apparatus of claim 1, wherein:
each bit line structure of the plurality of bit line structures comprises a first segment and a second segment of the conductive material,
the first segment extends, in a third direction, from a top surface of the plug to the second segment, and
the second segment extends, in the first direction, from the first segment to a top layer of the stack.

16. A method, comprising:
forming a stack comprising a plurality of oxide layers and a plurality of metal layers, the stack comprising a first level and a second level, wherein the stack comprises a first cavity that passes through at least a portion of the first level of the stack, the first cavity having a first width, wherein the stack comprises a second cavity that passes through at least a portion of the second level of the stack, the second cavity having a second width that is greater than the first width, and wherein the stack comprises a recess within a first oxide layer of the plurality of oxide layers of the second level of the stack, a third width of the second cavity at the first oxide layer greater than the first width and the second width based at least in part on the recess;
depositing layers of materials within the first cavity, the second cavity, and the recess, the materials comprising a protective liner, a storage material, and a second protective liner, wherein the second cavity has the second width throughout the second level of the stack after depositing the layers of the materials;
depositing, after depositing the layers of materials, a conductive material within the first cavity and the second cavity, wherein the conductive material forms a plug within the first cavity; and
etching the conductive material in the second level of the stack to form a plurality of bit line structures that extend from the plug through the second level of the stack, wherein each bit line structure of the plurality of bit line structures is physically isolated from other bit line structures within the second level of the stack based at least in part on etching the conductive material in the second level of the stack.

17. The method of claim 16, further comprising:
etching, as part of a backside formation, one or more layers in the first level of the stack and at least a portion of the plug, wherein etching the one or more layers in the first level of the stack and at least the portion of the plug forms a third cavity within the one or more layers and the portion of the plug; and
depositing, after etching the one or more layers, a source material within the third cavity to form a source for accessing a plurality of memory cells, wherein a remainder of the plug blocks the source material from entering remaining portions of the stack.

18. The method of claim 16, wherein the conductive material is deposited along a bottom of the second cavity, a first sidewall of the second cavity, and a second sidewall of the second cavity above the plug within the second level of the stack, and wherein etching the conductive material comprises:
etching, based at least in part on a mask, alternating regions of the conductive material to form a plurality of U-shaped strips of the conductive material that extend along the bottom of the second cavity, the first sidewall of the second cavity, and the second sidewall of the second cavity, and wherein each U-shaped strip of the plurality of U-shaped strips is in contact with the plug in the first level of the stack and is physically isolated from other U-shaped strips of the plurality of U-shaped strips within the second level of the stack by respective spaces based at least in part on the etching.

19. The method of claim 16, further comprising:
depositing, after depositing the conductive material, an oxide material within the second cavity, wherein etching the conductive material further comprises etching the oxide material, and wherein the oxide material reduces a thickness of the conductive material within the second level of the stack.

20. The method of claim 16, wherein forming the first level of the stack comprises:
depositing at least one oxide layer of the plurality of oxide layers;
depositing at least one metal layer of the plurality of metal layers; and
forming the first cavity that extends through the at least one oxide layer and the at least one metal layer, wherein the at least one metal layer is configured to activate the plurality of bit line structures.

21. The method of claim 16, wherein forming the first level of the stack comprises:
depositing a second oxide layer of the plurality of oxide layers; and
forming the first cavity that extends through the second oxide layer.

22. A method, comprising:
forming a stack comprising a plurality of oxide layers and a plurality of metal layers within a first level and a second level, wherein the stack comprises a first cavity that passes through the first level of the stack, the first cavity having a first width, wherein the stack comprises a second cavity that passes through the second level of the stack, the second cavity having a second width that is greater than the first width, and wherein the stack comprises a recess within a first oxide layer of the plurality of oxide layers of the second level of the stack, a third width of the second cavity at the first oxide layer greater than the first width and the second width based at least in part on the recess;
depositing a sacrificial material within the first cavity;
depositing, based at least in part on depositing the sacrificial material, a separation material within the recess and the second cavity;
etching the separation material to form a plurality of U-shaped separation material segments within the second level, wherein each U-shaped separation material segment of the plurality of U-shaped separation material segments is physically isolated from other U-shaped separation material segments within the second level based at least in part on etching the separation material; and
depositing, after etching the separation material and removing the sacrificial material from the first level of the stack, a conductive material within the first cavity and remaining portions of the second cavity that are between the plurality of U-shaped separation material segments, wherein the conductive material forms a plug within the first cavity and a plurality of bit line structures that extend from the plug through the second level of the stack, wherein each bit line structure of the plurality of bit line structures is physically isolated from other bit line structures of the plurality of bit line structures within the second level by one or more U-shaped separation material segments of the plurality of U-shaped separation material segments.

23. The method of claim 22, wherein forming the first level of the stack comprises:
depositing, after etching the separation material and removing the sacrificial material from the first level of the stack, a storage material within the first cavity and the second cavity, wherein:
the storage material extends along at least three sidewalls of the first cavity;
the storage material extends along at least three sidewalls of each U-shaped separation material segment of the plurality of U-shaped separation material segments within the second level of the stack; and
the storage material extends along a sidewall of the stack between each of the plurality of U-shaped separation material segments.

24. The method of claim 22, further comprising:
depositing, after depositing the conductive material, an oxide material within the first level of the stack, wherein the oxide material extends in a first direction within the plug based at least in part on depositing the oxide material.

25. The method of claim 22, further comprising:
etching, as part of a backside source formation after depositing the conductive material, one or more layers in the first level of the stack and at least a portion of the plug, wherein etching the one or more layers in the first level of the stack and at least the portion of the plug forms a third cavity within the one or more layers and the portion of the plug; and
depositing, after etching the one or more layers, a source material within the third cavity to form a source for accessing a plurality of memory cells, wherein a remainder of the plug and the separation material block the source material from entering remaining portions of the stack.
